(19) United States
(12) Patent Application Publication
(10) Pub. No.: US 2026/0372046 A1
(43) Pub. Date: Nov. 19, 2026

(54) PACKAGE STRUCTURE WITH OPTICAL ELEMENTS

(71) Applicant: Taiwan Semiconductor Manufacturing Company, Ltd., Hsinchu (TW)

(72) Inventors: Chih-Hsin LU, Tainan City (TW); Chia-Chia LIN, Kaohsiung City (TW); Ching-Ho CHIN, Taoyuan City (TW); Chung-Hao TSAI, Changhua County (TW); Chuei-Tang WANG, Taichung City (TW); Chen-Hua YU, Hsinchu City (TW)

(21) Appl. No.: 19/749,912

(22) Filed: Jul. 22, 2026

Related U.S. Application Data
(62) Division of application No. 18/320,398, filed on May 19, 2023.

(51) Int. Cl. H10W 20/20; G02B 6/122; H10D 30/01; H10D 30/43; H10D 30/67; H10D 62/10; H10D 64/01; H10W 20/00; H10W 70/63; G02B 6/12

(52) U.S. Cl. CPC H10W 20/20; G02B 6/122; H10D 30/014; H10D 30/43; H10D 30/6735; H10D 30/6757; H10D 62/121; H10D 64/017; H10W 20/023; H10W 70/635; G02B 2006/1204

(57) ABSTRACT

A package structure and a formation method are provided. The method includes forming electrical devices over a substrate and forming an interconnect structure over front sides of the electrical devices. The method also includes thinning the substrate and forming backside through vias connecting to backsides of the electrical devices. The method also includes attaching a waveguide layer over backsides of the electrical devices and forming conductive vias through the waveguide layer and electrically connected to the backside through vias.

### PRIORITY CLAIM AND CROSS-REFERENCE

This application is a Divisional Application of U.S. patent application 18/320,398 filed on May 19, 2023, the entirety of which is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A chip package not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a diagrammatic perspective view of intermediate stage of manufacturing an electrical device in accordance with some embodiments.

FIGS. 2A-1 to 2D-1, 2A-2 to 2D-2, and 2A-3 to 2D-3 illustrate the cross-sectional views of intermediate stages of manufacturing the electrical device shown along line Y_{SD}-Y_{SD}’, Y_{MG}-Y_{MG}’, and X-X’ in FIG. 1, respectively, in accordance with some embodiments.

FIGS. 3A to 3J illustrate the cross-sectional views of intermediate stages of manufacturing a package structure in accordance with some embodiments.

FIGS. 3E-1, 3E-2, and 3E-3 illustrate the cross-sectional view of the electrical device shown along line Y_{SD}-Y_{SD}’, Y_{MG}-Y_{MG}’, and X-X’ in FIG. 1, respectively, in accordance with some embodiments.

FIG. 4 illustrates a cross-sectional view of a package structure in accordance with some embodiments.

FIGS. 5A to 5D illustrate cross-sectional views of intermediate stages of manufacturing a package structure in accordance with some embodiments.

FIG. 6 illustrates a cross-sectional view of a package structure in accordance with some embodiments.

FIGS. 7A to 7B illustrate cross-sectional views of intermediate stages of manufacturing a package structure in accordance with some embodiments.

FIG. 8 illustrates a cross-sectional view of a package structure in accordance with some embodiments.

FIGS. 9A to 9B illustrate cross-sectional views of intermediate stages of manufacturing a package structure in accordance with some embodiments.

FIG. 10 illustrates a cross-sectional view of a package structure in accordance with some embodiments.

FIGS. 11A to 11C illustrate cross-sectional views of intermediate stages of manufacturing a package structure in accordance with some embodiments.

FIG. 12 illustrates a cross-sectional view of a package structure in accordance with some embodiments.

FIG. 13 illustrates a cross-sectional view of a package structure in accordance with some embodiments.

FIG. 14 illustrates a cross-sectional view of a package structure in accordance with some embodiments.

FIG. 15 illustrates a diagrammatic top view of a package structure in accordance with some embodiments.

FIGS. 16A to 16B illustrate cross-sectional representations of various stages of forming a package structure in accordance with some embodiments.

FIGS. 17 to 21 illustrate cross-sectional views of package structures in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments of the disclosure may relate to package structures such as three-dimensional (3D) packaging, 3D-IC devices, and 2.5D packaging. Embodiments of the disclosure form a package structure including a substrate that carries one or more dies or packages and a protective element (such as a protective lid) aside the dies or packages. The protective element may also function as a warpage-control element and/or heat dissipation element.

Other features and processes may also be included. For example, testing structures may be included to aid in the verification testing of the 3D packaging, 3DIC devices, and/or 2.5 D packaging. The testing structures may include, for example, test pads formed in a redistribution layer or on a substrate that allows testing to be conducted using probes or probe cards and the like. Verification testing may be performed on intermediate structures as well as the final structure. Additionally, the structures and methods disclosed herein may be used in conjunction with testing methodologies that incorporate intermediate verification of known good dies to increase the yield and decrease costs.

A package structure may include electrical devices and optical devices. The electrical devices may be formed in a first chip/wafer and the optical devices may be formed in a second chip/wafer, and the first chip/wafer and the second chip/wafer may be bonded together to form a photonic electronics integrated device. However, the size of the integrated device may be relatively large and the routing in the device may be relatively complicated.

Accordingly, in some embodiments of the disclosure, package structures with electrical devices and optical devices formed in a single structure and methods for manufacturing the same are provided. More specifically, an electrical device, such as a transistor, may be formed, and an interconnect structure may be formed at a front side of the electrical device, and an optical device may be formed at a backside of the electrical device. In addition, conductive structures may be electrically connected to the backside of the transistor, so that conductive structures formed at the front side of the electrical device may be electrically connected to conductive structures formed at the backside of the electrical device. Therefore, the electrical routing in the package structure may be relatively short, and the size of the package structure may be reduced.

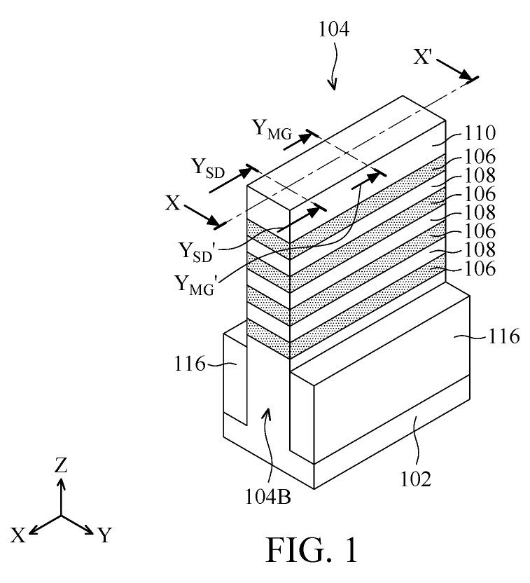

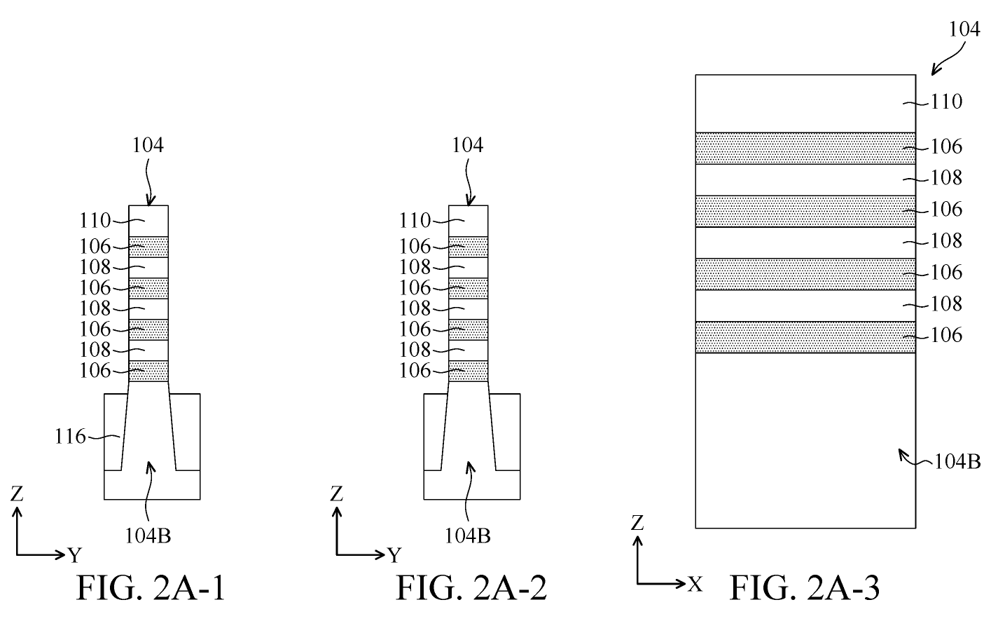

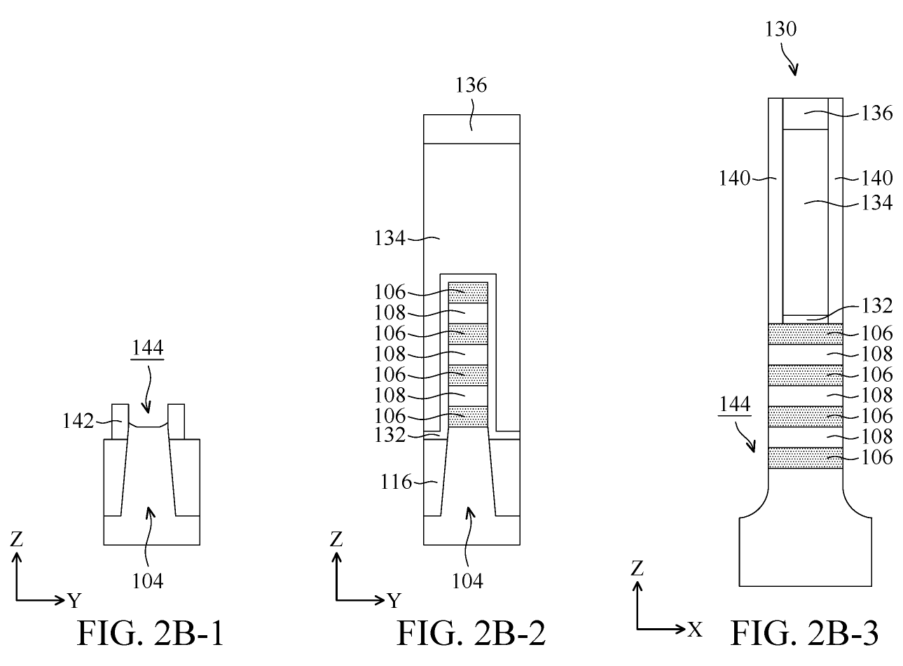

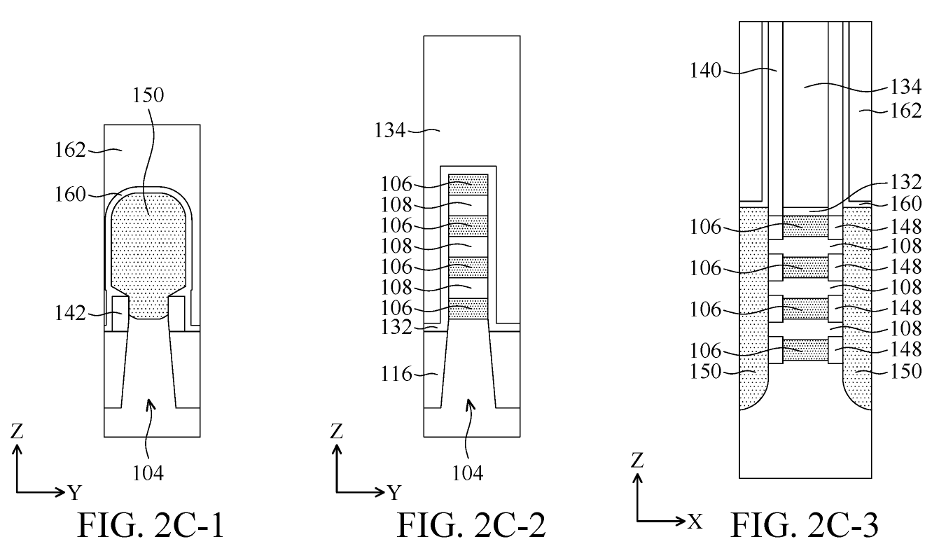

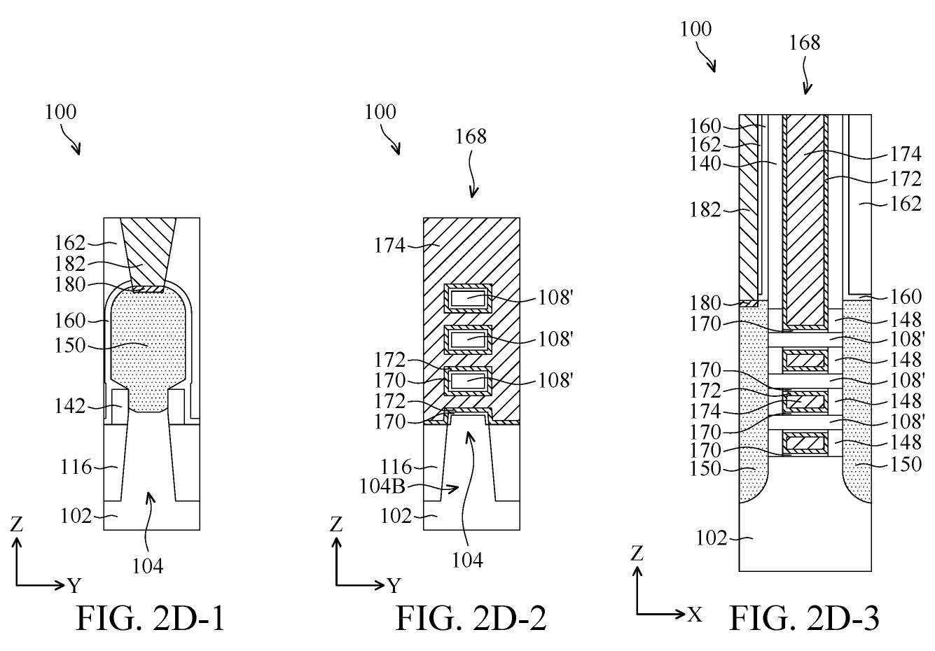

FIG. 1 illustrates a diagrammatic perspective view of intermediate stage of manufacturing an electrical device 100 in accordance with some embodiments. FIGS. 2A-1-2D-1,2A-2-2D-2 and 2A-3-2D-3 illustrate the cross-sectional views of intermediate stages of manufacturing the electrical device 100 shown along line Y_{SD}-Y_{SD}’ (i.e. in the Y direction), Y_{MG}-Y_{MG}’ (i.e. in the Y direction), and X-X’ (i.e. in the X direction) in FIG. 1, respectively, in accordance with some embodiments. More specifically, FIGS. 2A-1, 2A-2, and 2A-3, illustrate the cross-sectional views of the intermediate stages of manufacturing the electrical device 100 shown in FIGS. 1, and FIGS. 2B-1-2D-1,2B-2 -2D-2, 2B-3-2D-3 illustrate the cross-sectional views of the intermediate stages of manufacturing the electrical device 100 afterwards in accordance with some embodiments. The electrical device 100 may be a transistor such as a nanostructure transistor (e.g. a nanosheet transistor, a nanowire transistor, a multi-bridge channel transistor, a nano-ribbon FET, or a gate all around (GAA) transistor).

First, a substrate 102 is formed and a semiconductor stack including first semiconductor material layers 106 and second semiconductor material layers 108 is formed over the substrate 102, as shown in FIG. 1 in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102 to form the semiconductor stack. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although four first semiconductor material layers 106 and three second semiconductor material layers 108 are shown in FIG. 1, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor stack over the substrate 102, the semiconductor stack is patterned to form a fin structure 104, as shown in FIG. 1 in accordance with some embodiments. The fin structure 104 may extend lengthwise in the X direction. In some embodiments, the patterning process includes forming a mask structure 110 over the semiconductor material stack and etching the semiconductor material stack and the underlying substrate 102 through the mask structure 110. In some embodiments, the mask structure 110 is a multilayer structure including a pad oxide layer and a nitride layer formed over the pad oxide layer. The pad oxide layer may be made of silicon oxide, which is formed by thermal oxidation or CVD, and the nitride layer may be made of silicon nitride, which is formed by CVD, such as LPCVD or plasma-enhanced CVD (PECVD). In some embodiments, the fin structure 104 includes base fin structure 104B and the semiconductor stack, including the first semiconductor material layers 106 and the second semiconductor material layers 108, formed over the base fin structure 104B.

After the fin structure 104 is formed, an isolation structure 116 is formed around the fin structure 104, as shown in FIGS. 1, 2A-1, 2A-2, and 2A-3 in accordance with some embodiments. The isolation structure 116 is configured to electrically isolate active regions (e.g. the fin structure 104) of the semiconductor structure and is also referred to as shallow trench isolation (STI) feature in accordance with some embodiments.

More specifically, an insulating layer may be formed around and covering the fin structure 104, and the insulating layer may be recessed to form the isolation structure 116 with the fin structure 104 protruding from the top surface of the isolation structure 116. In some embodiments, the insulating layer is made of silicon oxide, silicon nitride, silicon oxynitride (SiON), another suitable insulating material, or a combination thereof. In addition, liner layers (not shown) may be formed before forming the insulating layer, and the liner layers may also be recessed with the insulating layer to form the isolation structure 116. In some embodiments, the liner layers include multiple dielectric material layers.

Afterwards, a dummy gate structure 130 is formed across the fin structure 104, and gate spacers 140 and fin spacers 142 are formed on sidewalls of the dummy gate structure 130, as shown in FIGS. 2B-1, 2B-2, and 2B-3 in accordance with some embodiments. The dummy gate structure 130 may be used to define the channel regions of the resulting transistor structure.

In some embodiments, the dummy gate structure 130 includes a dummy gate dielectric layer 132 and a dummy gate electrode layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 132 is formed using thermal oxidation, CVD, ALD, physical vapor deposition (PVD), another suitable method, or a combination thereof.

In some embodiments, the dummy gate electrode layer 134 is made of conductive material includes polycrystalline-silicon (poly-Si), poly-crystalline silicon-germanium (poly-SiGe), or a combination thereof. In some embodiments, the dummy gate electrode layer 134 is formed using CVD, PVD, or a combination thereof.

In some embodiments, a hard mask layer 136 is formed over the dummy gate electrode layer 134. In some embodiments, the hard mask layer 136 includes multiple layers, such as an oxide layer and a nitride layer. In some embodiments, the oxide layer is silicon oxide, and the nitride layer is silicon nitride.

The formation of the dummy gate structure 130 may include conformally forming a dielectric material as the dummy gate dielectric layers 132. Afterwards, a conductive material may be formed over the dielectric material as the dummy gate electrode layers 134, and the hard mask layer 136 may be formed over the conductive material. Next, the dielectric material and the conductive material may be patterned through the hard mask layer 136 to form the dummy gate structure 130.

After the dummy gate structure 130 is formed, a spacer layer may be formed to cover the top surfaces and the sidewalls of the dummy gate structure 130 and the fin structure 104, and an etching process may be performed to form the gate spacers 140, the fin spacers 142, and source/drain recesses 144 in the fin structure 104, as shown in FIGS. 2B-1, 2B-2, and 2B-3 in accordance with some embodiments. The gate spacers 140 may be configured to separate source/drain structures (formed afterwards) from the dummy gate structure 130, and the fin spacers 142 may be configured to confine the growth of the source/drain structures formed therein.

In some embodiments, the spacer layer is made one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. After the spacer layer is formed, the spacer layer is etched to form the gate spacers 140 on opposite sidewalls of the dummy gate structure 130 and to form the fin spacers 142 covering the sidewalls of the fin structure 104 in accordance with some embodiments. In addition, the portions of the fin structure 104 not covered by the dummy gate structure 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 116 is also slightly etched during the etching process.

After the source/drain recesses 144 are formed, the first semiconductor material layers 106 exposed by the source/drain recesses 144 are laterally recessed to form notches, and inner spacers 148 are formed in the notches, as shown in FIGS. 2C-1, 2C-2, and 2C-3 in accordance with some embodiments. In some embodiments, an etching process is performed to laterally recess the first semiconductor material layers 106 of the fin structure 104 from the source/drain recesses 144. In some embodiments, during the etching process, the first semiconductor material layers 106 have a greater etching rate (or etching amount) than the second semiconductor material layers 108, thereby forming notches between the adjacent second semiconductor material layers 108. In some embodiments, the second semiconductor material layers 108 are also slightly etched during the etching process, so that the portions of the second semiconductor material layers 108 exposed by the notches become thinner than other portions in accordance with some embodiments. In some embodiments, the etching process is an isotropic etching such as dry chemical etching, remote plasma etching, wet chemical etching, another suitable technique, and/or a combination thereof.

Next, the inner spacers 148 are formed in the notches between the second semiconductor material layers 108 in accordance with some embodiments. The inner spacers 148 may be configured to separate the source/drain structures and the gate structure formed in subsequent manufacturing processes. As described previously, since the second semiconductor material layers 108 are also partially etched when forming the notches, the inner spacers 148 formed in the notches are thicker than the thicknesses of the first semiconductor material layers 106 in accordance with some embodiments. In addition, the inner spacers 148 have curve sidewalls in accordance with some embodiments. In some embodiments, the inner spacers 148 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the inner spacers 148 are formed, source/drain structures 150 are formed in the source/drain recesses 144, and a contact etch stop layer 160 and an interlayer dielectric layer 162 are formed over the source/drain structures 150, as shown in FIGS. 2C-1, 2C-2, and 2C-3 in accordance with some embodiments. The source/drain structures described herein may refer to a source or a drain, individually or collectively dependent upon the context.

In some embodiments, the source/drain structures 150 are formed using epitaxial growth processes, such as MBE, MOCVD, VPE, other applicable epitaxial growth process, or a combination thereof. In some embodiments, the source/drain structures 150 are made of any applicable material, such as Ge, Si, GaAs, AlGaAs, SiGe, GaAsP, SiP, SiC, SiCP, or a combination thereof. In some embodiments, the source/drain structures 150 are in-situ doped during the epitaxial growth process. In some embodiments, the source/drain structures 150 are doped in one or more implantation processes after the epitaxial growth process.

After the source/drain structures 150 are formed, the contact etch stop layer (CESL) 160 is conformally formed to cover the source/drain structures 150, and the interlayer dielectric (ILD) layer 162 is formed over the contact etch stop layers 160 in accordance with some embodiments. In some embodiments, the contact etch stop layer 160 is made of a dielectric materials, such as silicon nitride, silicon oxide, silicon oxynitride, another suitable dielectric material, or a combination thereof. The dielectric material of the contact etch stop layers 160 may be conformally deposited over the semiconductor structure by performing CVD, ALD, other application methods, or a combination thereof.

The interlayer dielectric layer 162 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 162 may be formed by chemical vapor deposition (CVD), physical vapor deposition, (PVD), atomic layer deposition (ALD), or other applicable processes.

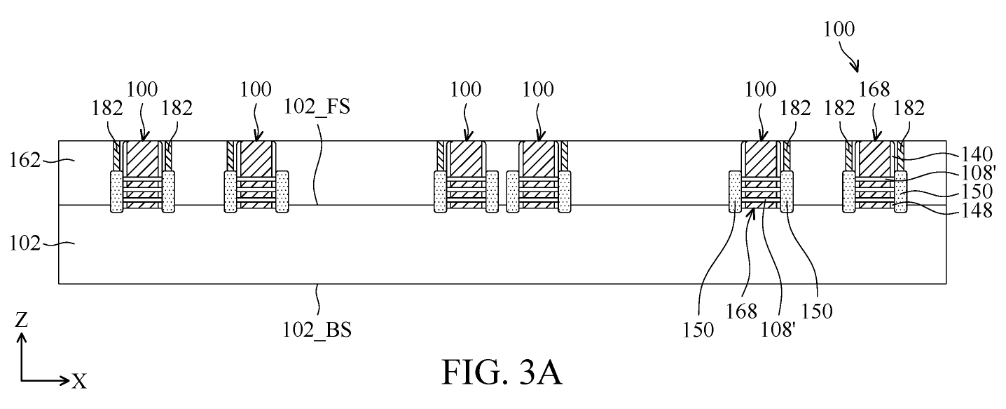

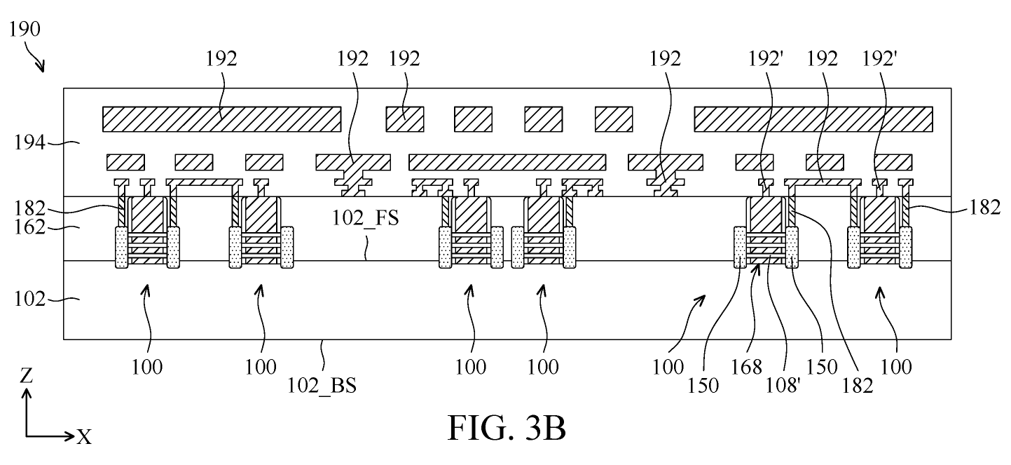

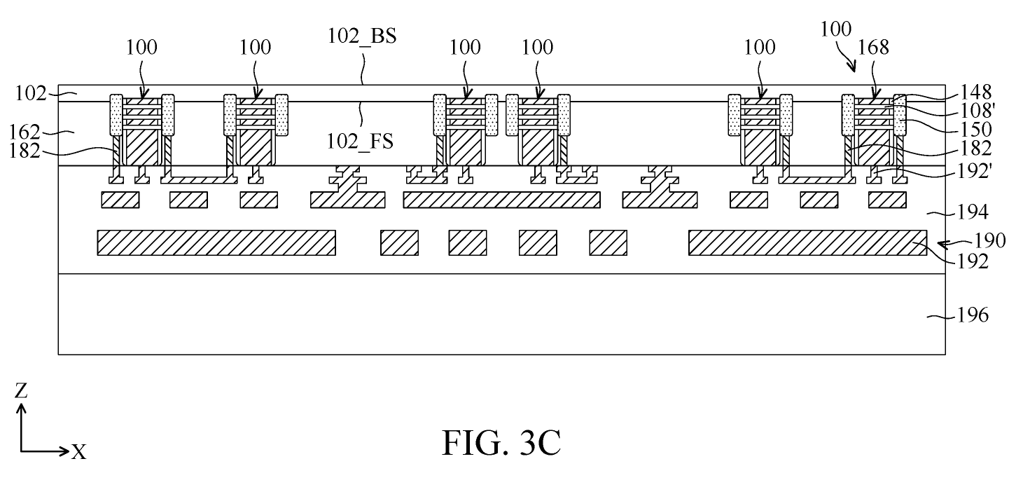

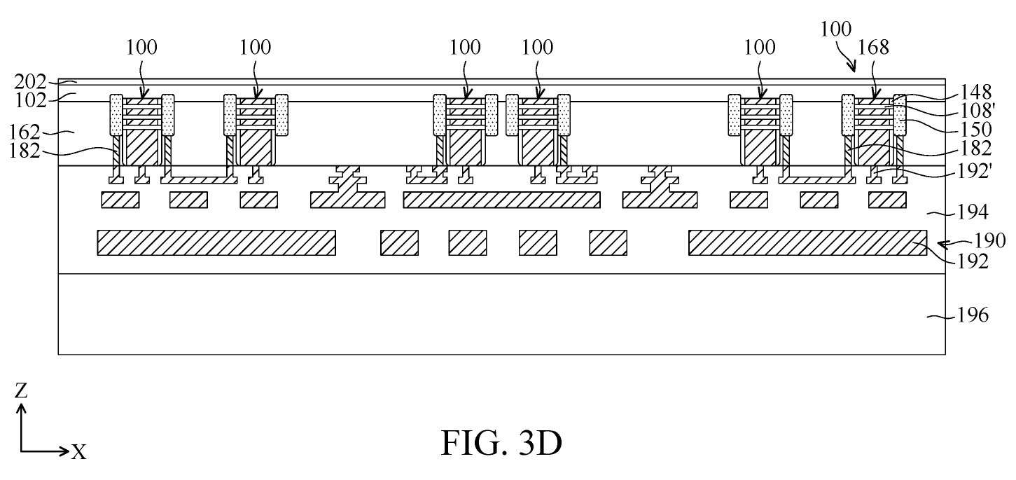

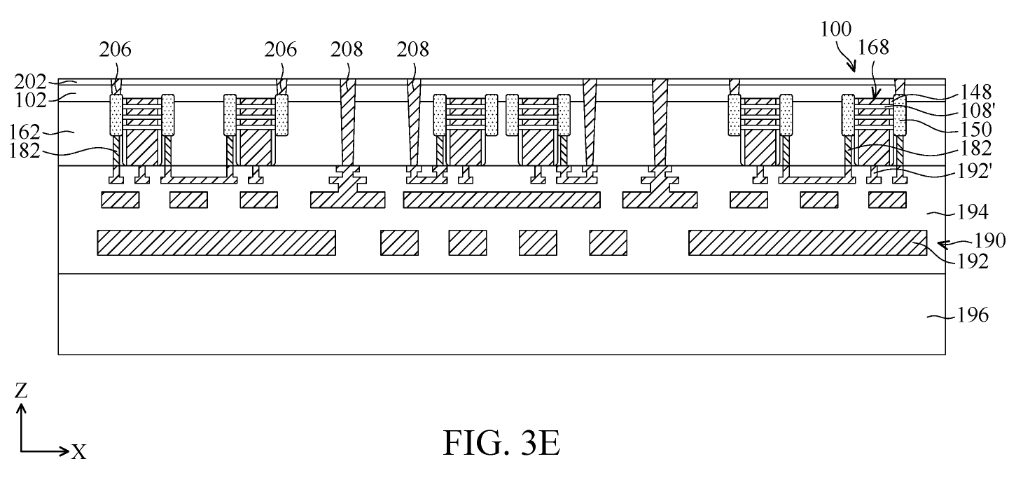

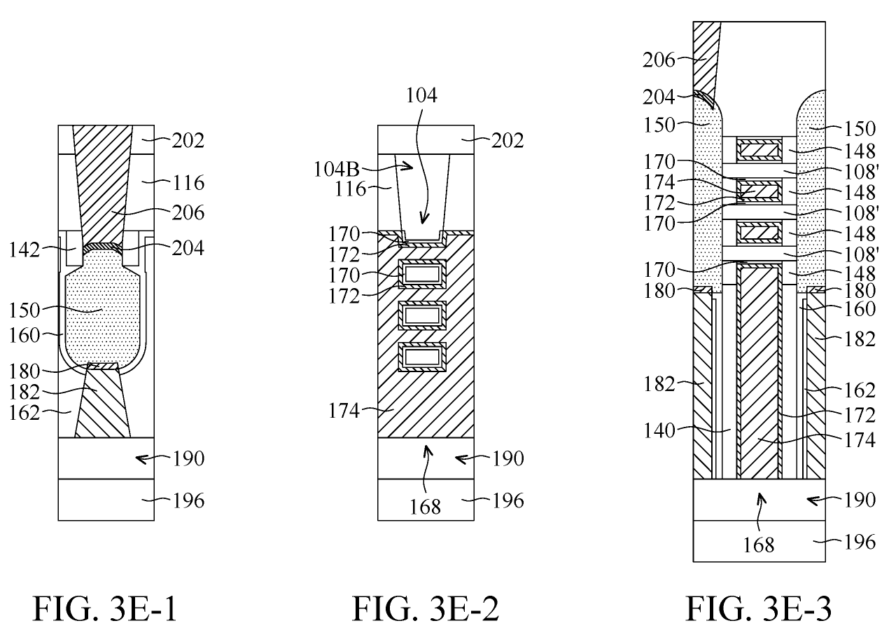

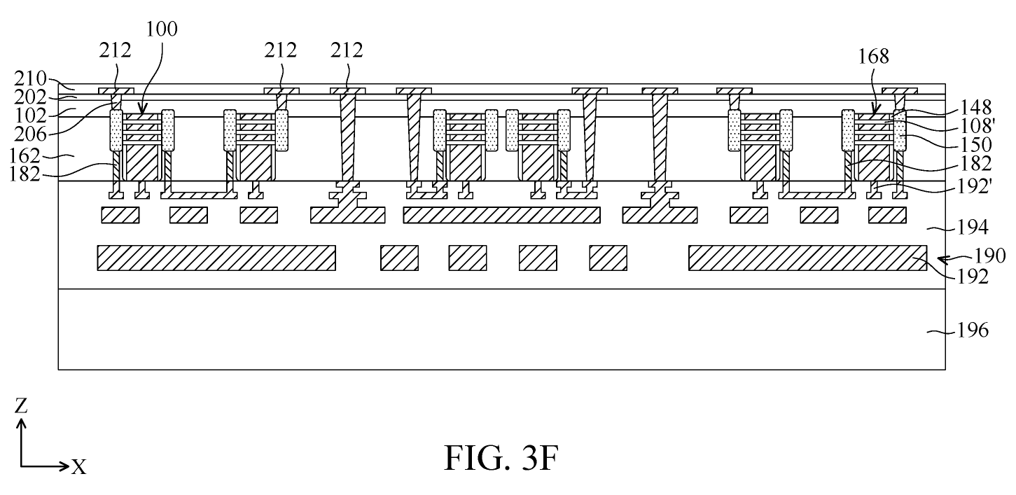

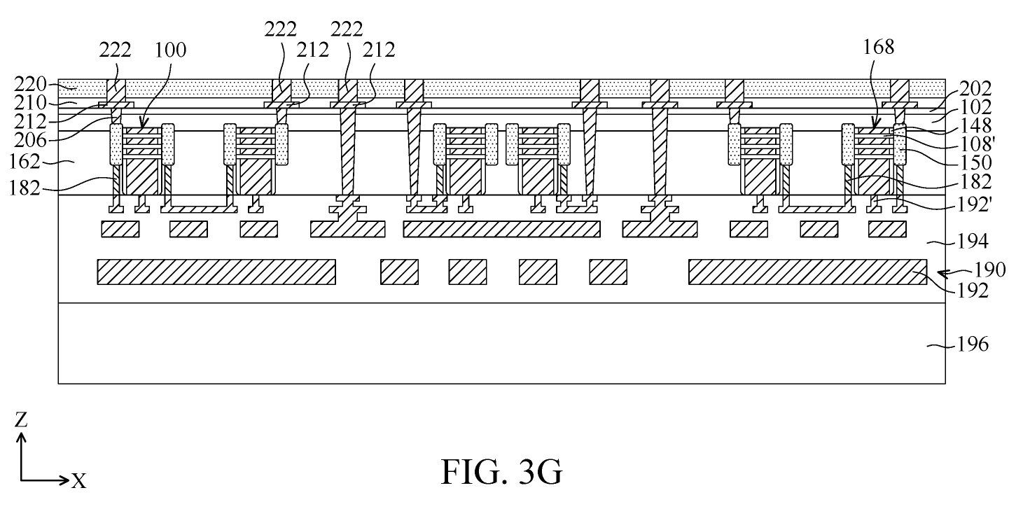

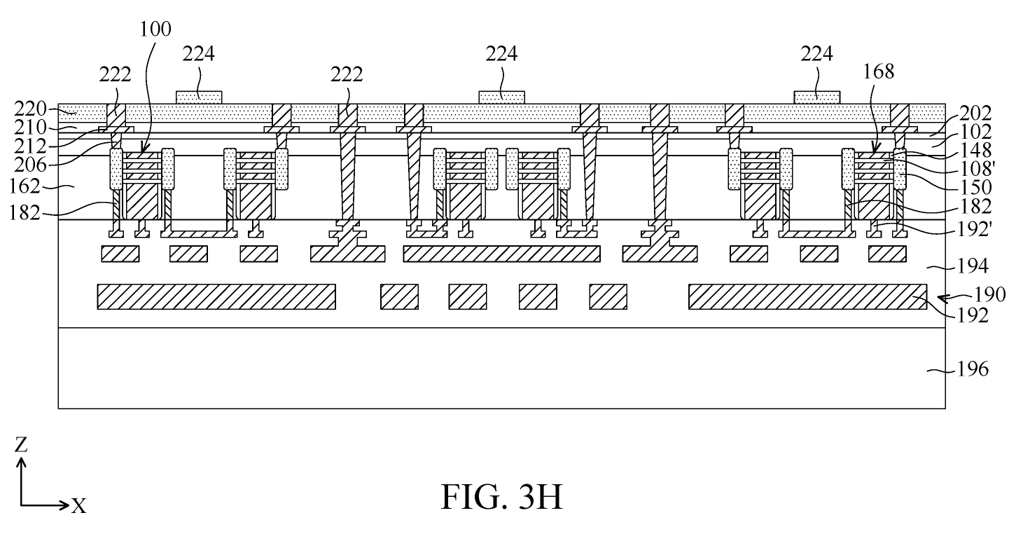

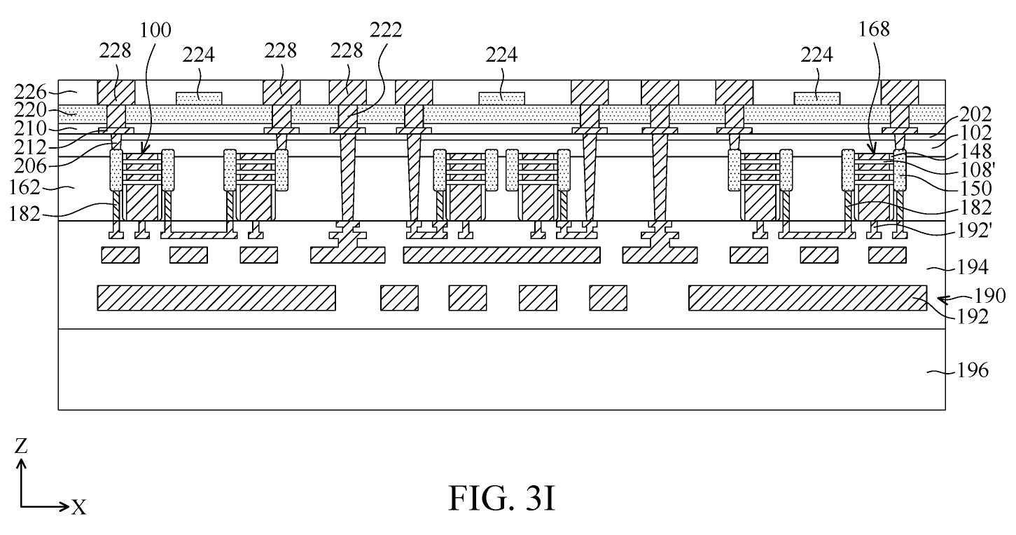

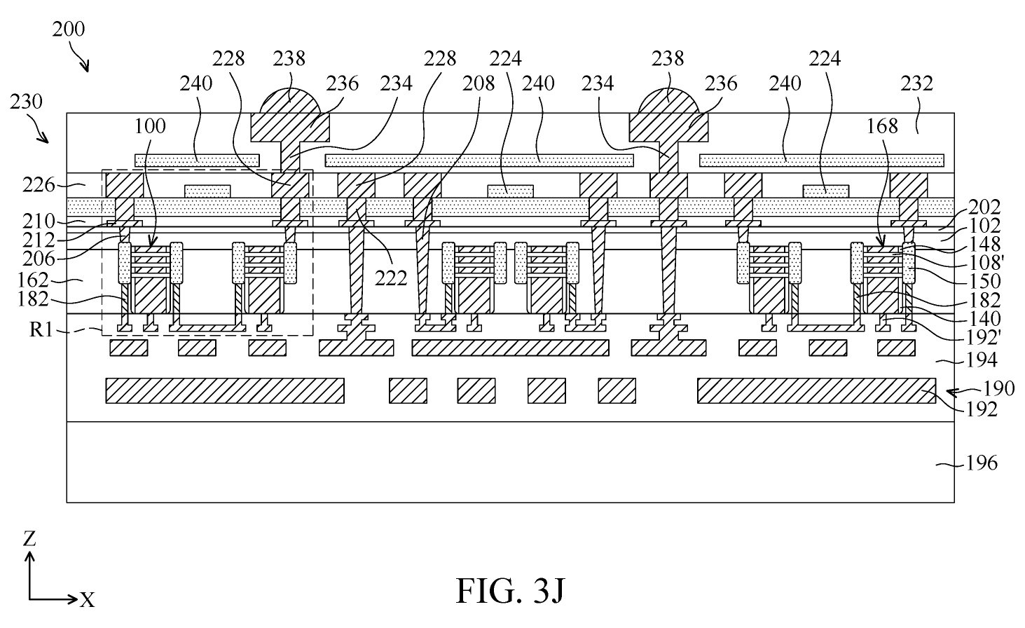

After the contact etch stop layer 160 and the interlayer dielectric layer 162 are deposited, a planarization process such as CMP or an etch-back process is performed until the dummy gate electrode layer 134 is exposed in accordance with some embodiments. Next, the dummy gate structure 130 and the first semiconductor material layers 106 are removed to form a gate trench, and a gate structure 168 is formed in the gate trench, as shown in FIGS. 2D-1, 2D-2, and 2D-3 in accordance with some embodiments. More specifically, the dummy gate structure 130 and the first semiconductor material layers 106 are removed to form channel structures (e.g. nanostructures) 108’ with the second semiconductor material layers 108 of the fin structure 104 respectively in accordance with some embodiments. As shown in FIG. 2D-3, the channel structures 108’ are vertically suspended over the substrate 102 and spaced apart from each other in the Z direction in accordance with some embodiments. In addition, the channel structures 108’ laterally extend between and interposing the source/drain structures 150 respectively in the X direction in accordance with some embodiments. Although not clearly shown in FIG. 2D-2, the channel structures 108’ and the base fin structures 104B may have rounded corners.

The removal process may include one or more etching processes. For example, when the dummy gate electrode layer 134 may be made of polysilicon, and a wet etchant such as a tetramethylammonium hydroxide (TMAH) solution may be used to selectively remove the dummy gate electrode layer 134. Afterwards, the dummy gate dielectric layer 132 may be removed using a plasma dry etching, a dry chemical etching, and/or a wet etching. The first semiconductor material layers 106 may be removed by performing a selective wet etching process, such as an APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

After the channel structures 108’ are formed, an interfacial layer 170, a gate dielectric layer 172, and a gate stack 174 are formed to wrap the channel structures 108’ as the gate structure 168, as shown in FIGS. 2D-1, 2D-2, and 2D-3 in accordance with some embodiments.

The interfacial layer 170 may be used to improve the interfaces between the channel structures 108’ and dielectric layers formed afterwards. In addition, the interfacial layer 170 may be able to help suppressing the mobility degradation of charge carries in the channel structures 108’ that serve as channel regions of the transistors. In some embodiments, the interfacial layer 170 is an oxide layer formed by performing a thermal process. In some embodiments, the interfacial layer 170 has a thickness in a range from about 0.5nm to about 1.5nm.

After the interfacial layer 170 is formed, the gate dielectric layer 172 is conformally formed in the gate trenches in accordance with some embodiments. In some embodiments, the gate dielectric layer 172 covers the interfacial layer 170 and wraps around the channel structures 108’. In some embodiments, the gate dielectric layer 172 is made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al2O₃) alloy, other applicable high-k dielectric materials, or a combination thereof. In some embodiments, the gate dielectric layer 172 is formed using CVD, ALD, other applicable methods, or a combination thereof.

Next, the gate stack 174 is formed over the gate dielectric layers 172 in accordance with some embodiments. In some embodiments, the gate stack 174 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate stack 174 is formed using CVD, ALD, electroplating, another applicable method, or a combination thereof.

After the gate structure 168 is formed, a silicide layer 180 and a source/drain contact 182 are formed over the source/drain structures 150, as shown in FIGS. 2D-1, 2D-2, and 2D-3 in accordance with some embodiments. More specifically, a contact trench may be formed through the contact etch stop layer 160 and the interlayer dielectric layer 162 to expose the source/drain structures 150. Afterwards, the silicide layer 180 is formed over the exposed portion of the source/drain structures 150, and the source/drain contact 182 is formed in the contact trench over the silicide layer 180 in accordance with some embodiments.

The silicide layer 180 may be formed by forming a metal layer over the top surface of the source/drain structures 150 and annealing the metal layer so the metal layer reacts with the source/drain structures 150 to form the silicide layer 180. The unreacted metal layer may be removed after the silicide layer 180 is formed.

In some embodiments, the source/drain contact 182 is made of a conductive material including aluminum (Al), copper (Cu), tungsten (W), titanium (Ti), tantalum (Ta), titanium nitride (TiN), cobalt, tantalum nitride (TaN), nickel silicide (NiSi), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The source/drain contact 182 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a plasma enhanced chemical vapor deposition (PECVD) process, although other applicable processes, such as physical vapor deposition or a thermal process, may be used as an alternative. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

As shown in FIGS. 2D-1, 2D-2, and 2D-3, the electrical device 100 includes the channel layers 108’ suspended over the substrate 102 in the Z direction, the source/drain structures 150 attached to the opposite sides of the channel layers 108’ in the X direction, and the gate structure 168 wrapping around the channel layers 108’ and extending along the Y direction in accordance with some embodiments. In addition, the source/drain contact 182 is connected to the front side of the source/drain structures 150 of the electrical device 100.

FIGS. 3A to 3J illustrate the cross-sectional views of intermediate stages of manufacturing a package structure 200 in accordance with some embodiments. More specifically, a number of the electrical devices 100 shown in FIGS. 2D-1, 2D-2, and 2D-3 are formed over a front side 102_FS of the substrate 102, as shown in FIG. 3A in accordance with some embodiments. The front side 102_FS of the substrate 102 is opposite to a backside 102_BS of the substrate 102. The structure of the electrical devices 100 shown in FIGS. 3A to 3J have been simplified for clarity, and the detail structure and the method for manufacturing them are shown in FIGS. 1, 2A-1-2D-1, 2A-2, and 2A-3-2D-3 in accordance with some embodiments. In addition, the number and the arrangements of the electrical devices 100 in the package structure 200 may be altered according to its application.

After the electrical devices 100 are formed, an interconnect structure 190 is formed over the interlayer dielectric layer 162, as shown in FIG. 3B in accordance with some embodiments. That is, the interconnect structure 190 is formed over the front sides of the electrical devices 100, while the substrate 102 is located at the backsides of the electric devices 100 in accordance with some embodiments.

In some embodiments, the interconnect structure 190 is a front-side interconnect structure. In some embodiments, the interconnect structure 190 includes conductive structures 192 (e.g. vias and metal lines) formed in multiple dielectric layers 194. In some embodiments, the source/drain contacts 182 are electrically connected to the conductive structures 192 in the interconnect structure 190. In some embodiments, the interconnect structure 190 further comprises contact plugs 192’ landing on the gate structures 168 and electrically connected to the gate structures 168.

The dielectric layer 194 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 194 may be formed by chemical vapor deposition (CVD), physical vapor deposition, (PVD), atomic layer deposition (ALD), or other applicable processes.

In some embodiments, the conductive structures 192 and the contact plugs 192’ are made of conductive materials, such as copper (Cu), copper alloy, aluminum (Al), aluminum alloys, combinations thereof or another applicable material. In some embodiments, the conductive structures 192 and the contact plugs 192’ are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

After the interconnect structure 190 is formed, a carrier substrate 196 is attached to the interconnect structure 190 to provide the semiconductor structure with temporary mechanical and structural support in subsequent manufacturing process. The carrier substrate 196 may include glass, silicon oxide, aluminum oxide, metal, a combination thereof, and/or the like. In some embodiments, the interconnect structure 190 is attached to the carrier substrate 196 by an adhesive layer (not shown). The adhesive layer is used as a temporary adhesive layer. The adhesive layer may be glue or a tape.

Next, the structure may be flipped upside down to form elements over the backside 102_BS of the substrate 102. More specifically, after the carrier substrate 196 is attached to the interconnect structure 190, the substrate 102 is turned upside down, and a planarization process is performed to the backside 102_BS of the substrate 102, as shown in FIG. 3C in accordance with some embodiments. In some embodiments, the planarization process is performed to the substrate 102 until the isolation structure 116 (not shown in FIG. 3C) is exposed. In some embodiments, after the planarization process is performed, the remaining substrate 102 has a thickness in a range from about 5nm to about 100nm.

Next, a dielectric layer 202 is formed over the backside 102_BS of the substrate 102, as shown in FIG. 3D in accordance with some embodiments. In some embodiments, the dielectric layer 202 is made of a low k dielectric material having a k value lower than 7. In some embodiments, the dielectric layer 202 is made of SiO2, SiN, SiCN, SiOC, SiOCN, or the like. The dielectric layer 202 may be formed by chemical vapor deposition (CVD), physical vapor deposition, (PVD), atomic layer deposition (ALD), or other applicable processes.

After the dielectric layer 202 is formed, backside silicide layers 204 and backside through vias 206 are formed, as shown in FIGS. 3E, 3E-1, 3E-2, and 3E-3 in accordance with some embodiments. More specifically, FIGS. 3E-1, 3E-2, and 3E-3 illustrate the cross-sectional view of the electrical device 100 in the package structure 200 shown along line Y_{SD}-Y_{SD}’ (i.e. in the Y direction), Y_{MG}-Y_{MG}’ (i.e. in the Y direction), and X-X’ (i.e. in the X direction) in FIG. 1, respectively, in accordance with some embodiments.

In some embodiments, backside through vias trenches are formed through the dielectric layer 202 and the substrate 102, so that the bottom portions of the source/drain structures 150 are exposed. In some embodiments, the bottom portions of the source/drain structures 150 are also slightly removed. Afterwards, the backside silicide layers 204 are formed over the exposed source/drain structures 150, and the backside through vias 206 are formed over the backside silicide layers 204, as shown in FIGS. 3E-1, 3E-2, and 3E-3 in accordance with some embodiments. In some embodiments, the backside silicide layers 204 are formed by forming metal layers over the exposed surfaces of the source/drain structures 150 and annealing the metal layers so the metal layers react with the source/drain structures 150 to form the backside silicide layers 204. The unreacted metal layers are then removed after the backside silicide layers 204 are formed in accordance with some embodiments. In some embodiments, the backside silicide layers 204 are N-type epi silicide such as TiSi, CrSi, TaSi, MoSi, ZrSi, HfSi, ScSi, Ysi, HoSi, TbSI, GdSi, LuSi, DySi, ErSi, YbSi, or the like. In some embodiments, the backside silicide layers 204 are P-type epi silicide such as NiSi, CoSi, MnSi, Wsi, FeSi, RhSi, PdSi, RuSi, PtSi, IrSi, OsSi, or the like.

After the backside silicide layers 204 are formed, a conductive filling layer is formed to fill the backside through via trenches, and a polishing process is performed to form the backside through vias 206, as shown in FIGS. 3E, 3E-1, 3E-2, and 3E-3 in accordance with some embodiments. In some embodiments, backside through vias 208 are further formed through the dielectric layer 202, the substrate 102, and the interlayer dielectric layer 162 and are electrically connected to the conductive structures 192 in the interconnect structure 190. Accordingly, the electrical signals at the backsides of the substrate 102 may be transferred to the elements formed at the front side of the substrate 102. As shown in FIGS. 3E, 3E-1, 3E-2, and 3E-3 the source/drain contacts 182 are landed on the front side of the source/drain structures 150 of the electrical devices 100, and the backside through vias 206 are landed on the backside of the source/drain structures 150 of the electrical devices 100 in accordance with some embodiments.

In some embodiments, the backside through vias 206 and 208 are made of W, Ru, Co, Cu, Ti, TiN, Ta, TaN, Mo, Ni, other applicable conductive materials, or a combination thereof. The backside through vias 206 and 208 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

A liner layer (not shown) and/or a barrier layer (not shown) may be formed on the sidewalls of the backside through vias 206 and 208. For example, the liner layer may include silicon nitride, although any other applicable dielectric may be used as an alternative. For example, the barrier layer may include tantalum nitride, although other materials, such as tantalum, titanium, titanium nitride, or the like, may also be used. The liner layer and the barrier layers may be formed using a process such as chemical vapor deposition (CVD), physical vapor deposition (PVD), plasma enhanced CVD (PECVD), plasma enhanced physical vapor deposition (PEPVD), atomic layer deposition (ALD), or another applicable deposition processes. In some embodiments, each of the backside through vias 206 and 208 has a width in a range from about 15 nm to about 300 nm in the X direction and/or the Y direction. In some other embodiments, the substrate 102 is completely removed after the backside through vias 206 and 208 are formed.

Afterwards, a dielectric layer 210 is formed over the backside of the electrical devices 100 and conductive structures 212 are formed in the dielectric layer 210, as shown in FIG. 3F in accordance with some embodiments. In some embodiments, the conductive structures 212 are metal lines embedded in the dielectric layer 210. In some embodiments, the dielectric layer 210 includes multiple layers made of low k dielectric materials having a k value lower than 7. In some embodiments, the dielectric layer 210 is made of SiO₂, SiN, SiCN, SiOC, SiOCN, or the like. The dielectric layer 210 may be formed by chemical vapor deposition (CVD), physical vapor deposition, (PVD), atomic layer deposition (ALD), or other applicable processes.

In some embodiments, the conductive structures 212 are made of W, Ru, Co, Cu, Ti, TiN, Ta, TaN, Mo, Ni, other applicable conductive materials, or a combination thereof. The conductive structures 212 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Afterwards, a waveguide layer 220 is disposed over the dielectric layer 210, and conductive vias 222 are formed through the waveguide layer 220, as shown in FIG. 3G in accordance with some embodiments. The waveguide layer 220 is configured to transport the optical signal in the optical devices. More specifically, the waveguide layer 220 provides an optical medium for the light transmitting. For example, the optical signal can be trapped and guided by the waveguide layer 220.

In some embodiments, the waveguide layer 220 is a LiNbO₃ (lithium niobate) layer. In some embodiments, the waveguide layer 220 has a thickness in a range from about 300nm to about 800nm in Z direction. The thickness of the waveguide layer 220 is controlled so that the transport of light will be confined within the waveguide layer 220. In some embodiments, the waveguide layer 220 is a wafer and is directly bonded to the dielectric layer 210. In some embodiments, the width of the waveguide layer 220 is substantially equal to the width of the substrate 102 in both X direction and Y direction. The waveguide layer 220 may be attached to the dielectric layer 210 through an adhesive layer, such as an oxide layer.

After the waveguide layer 220 is disposed, the waveguide layer 220 and the dielectric layer 210 are patterned to form trenches, and the conductive vias 222 are formed in the trenches, as shown in FIG. 3G in accordance with some embodiments. In some embodiments, the conductive structures 212 are exposed by the trenches, and therefore the conductive vias 222 are in direct contact with the conductive structures 212. In some embodiments, the conductive vias 222 are made of W, Ru, Co, Cu, Ti, TiN, Ta, TaN, Mo, Ni, other applicable conductive materials, or a combination thereof. The conductive vias 222 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Next, waveguide features 224 are formed over the waveguide layer 220, as shown in FIG. 3H in accordance with some embodiments. In some embodiments, the waveguide features 224 include optical waveguides, such as ridge waveguides, rib waveguides, buried channel waveguides, and diffused waveguides, or couplers, such as grating couplers, and edge couplers. The waveguide features 224 are configured to guide the optical signal in the optical devices. More specifically, when a voltage is applied to the optical devices, the refractive index of the waveguide layer 220 may be altered, and light will be transported between the interface between the waveguide features 224 and the waveguide layer 220. In some embodiments, the waveguide features 224 and the waveguide layer 220 are made of different materials. In some embodiments, the waveguide features 224 are made of SiN. In some embodiments, the waveguide features 224 have a thickness in a range from about 100nm to about 800nm in the Z direction.

In some embodiments, the waveguide features 224 are formed by performing a deposition process to form a material layer and patterning the material layer to form the waveguide features 224. The deposition process may include chemical vapor deposition (CVD), physical vapor deposition (PVD), plasma enhanced CVD (PECVD), plasma enhanced physical vapor deposition (PEPVD), atomic layer deposition (ALD), or another applicable deposition processes. The patterning process may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

Afterwards, a dielectric layer 226 and conductive structures 228 are formed in the dielectric layer 226, as shown in FIG. 3I in accordance with some embodiments. In some embodiments, the conductive structures 228 are contact metals formed in the dielectric layer 226. In some embodiments, the dielectric layer 226 are multiple layers made of low k dielectric materials having a k value lower than 7. In some embodiments, the dielectric layer 226 is made of SiO₂, SiN, SiCN, SiOC, SiOCN, or the like. The dielectric layer 226 may be formed by chemical vapor deposition (CVD), physical vapor deposition, (PVD), atomic layer deposition (ALD), or other applicable processes.

In some embodiments, the conductive structures 228 are made of W, Ru, Co, Cu, Ti, TiN, Ta, TaN, Mo, Ni, other applicable conductive materials, or a combination thereof. The conductive structures 228 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

Next, an interconnect structure 230 is formed over the dielectric layer 226, as shown in FIG. 3J in accordance with some embodiments. The interconnect structure 230 may be a backside interconnect structure. The interconnect structure 230 may be used as a redistribution (RDL) structure for routing.

In some embodiments, the interconnect structure 230 includes a dielectric layer 232, contact plugs 234 and metal layers 236 embedded in the dielectric layer 232, and conductive bumps 238. In some embodiments, the interconnect structure 230 further includes waveguide features 240 embedded in the dielectric layer 232.

In some embodiments, the dielectric layer 232 includes multiple layers made of low k dielectric materials having a k value lower than 7. In some embodiments, the dielectric layer 232 is made of SiO2, SiN, SiCN, SiOC, SiOCN, or the like. The dielectric layer 232 may be formed by chemical vapor deposition (CVD), physical vapor deposition, (PVD), atomic layer deposition (ALD), or other applicable processes.

In some embodiments, the contact plugs 234 and the metal layers 236 are made of W, Ru, Co, Cu, Ti, TiN, Ta, TaN, Mo, Ni, other applicable conductive materials, or a combination thereof. The contact plugs 234 and the metal layers 236 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the conductive bumps 238 include a solder material. The solder material may be a tin-containing material. The tin-containing material may further include copper, silver, gold, aluminum, lead, one or more other suitable materials, or a combination thereof. In some embodiments, the solder material is lead-free.

In some embodiments, the waveguide features 240 include optical waveguides, such as ridge waveguides, rib waveguides, buried channel waveguides, and diffused waveguides, or couplers, such as grating couplers, and edge couplers. The waveguide features 240 are configured to guide the optical signal in the optical devices. In some embodiments, the waveguide features 240 and the waveguide features 224 are made of the same material. In some embodiments, the waveguide features 240 and the waveguide layer 220 are made of different materials. In some embodiments, the waveguide features 240 are made of SiN. In some embodiments, each of the waveguide features 240 have a thickness in a range from about 100nm to about 800nm in Z direction.

As described above, electrical devices 100 and optical devices (e.g. the waveguide layer 220 and the waveguide features 224 and 240) are formed over a same wafer in accordance with some embodiments. As shown in FIG. 3J, the package structure 200 includes a Mach-Zehnder modulator phase shifter region R1 in accordance with some embodiments. Since the Mach-Zehnder modulator phase shifter region R1 has both electrical devices and optical devices therein, light can be transport in the optical devices and the signals may be adjusted by the electrical devices. For example, the electrical devices 100 may receive and process the electrical signal, and the optical devices (e.g. the waveguide layer 220 and the waveguide features 224 and 240) may receive and process the optical signals. Since the electrical devices and the optical devices are formed on a single wafer, instead of formed on different chips and bonded together afterwards, the passage of the electrical signals and the optical signals may be reduced. That is, the routings of the optical signal or the electrical signal in the package structure 200 may be reduced, and the transmission speed of the electrical signals and the optical signals may be improved.

In addition, backside power delivery network (e.g. backside through vias 206) are formed at the backside of the electrical devices 100, so that the interconnect structures 190 and 230 may be formed at opposite sides of the electrical devices 100 and can be electrically connected to each other in accordance with some embodiments. Accordingly, the electrical routing in the package structure 200 may be simplified and reduced. In addition, the backside conductive structures (e.g. the contact plugs 234 and the metal layers 236) and optical elements (e.g. waveguide features 240) are integrated in the interconnect structure 230, so that the routing area may also be reduced.

After both the electrical devices and the optical devices are formed in the package structure 200 (e.g. a wafer), the package structure 200 may be diced into a number of chip structures. Each of the chip structures also includes both electrical devices and the optical devices formed therein.

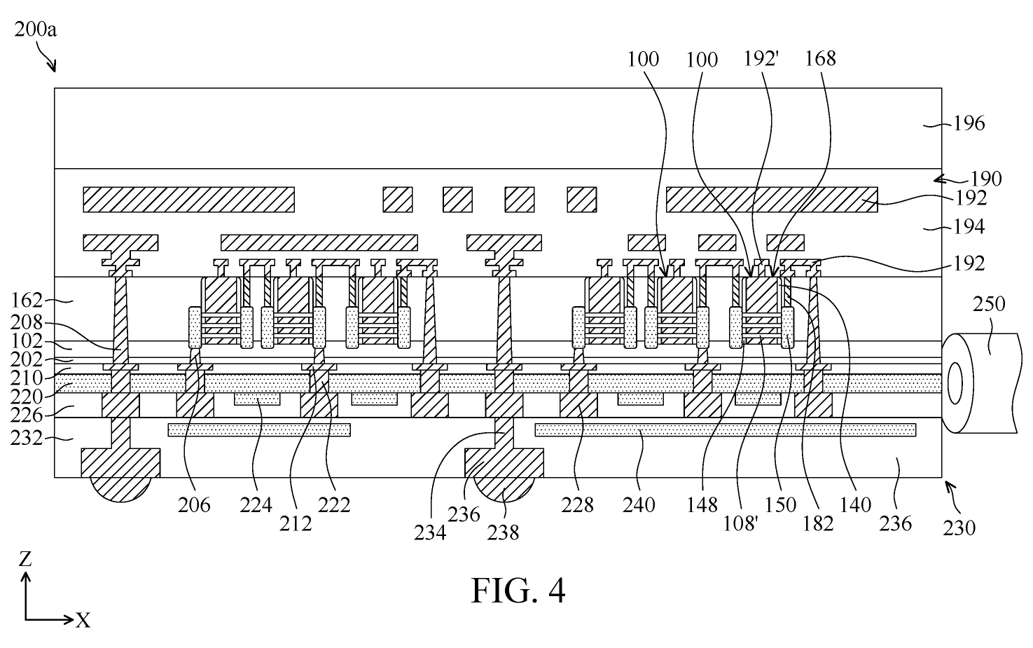

FIG. 4 illustrates a cross-sectional view of a package structure 200’ in accordance with some embodiments. The package structure 200’ may be similar to the package structure 200 described previously, except an optical fiber is attached to the package structure 200’ in accordance with some embodiments. Processes and materials for forming the package structure 200’ may be similar to, or the same as, those for forming the package structure 200 described previously and are not repeated herein.

More specifically, an optical fiber 250 is attached to the sidewall of the waveguide layer 220, as shown in FIG. 4 in accordance with some embodiments. In some embodiments, the optical fiber 250 laterally overlaps the waveguide layer 220 (e.g. in the X direction). In some embodiments, the optical fiber 250 also laterally overlaps the waveguide features 224 (e.g. in the X direction). The optical fiber 250 may be an edge couple device configured to be an input/output port to the optical signal of the optical devices in the package structure 200’. The optical fiber 250 may be held in place using an optical glue (not separately illustrated). In some embodiments, the optical glue includes a polymer material such as epoxy-acrylate oligomers, and may have a refractive index between about 1 and about 3.

Similar to the package structure 200, the package structures 200’ includes both the electrical devices 100 and the optical devices (e.g. the waveguide layer 220 and the waveguide features 224 and 240) formed over a single wafer, so that the electrical and optical communication and computing may be improved. In addition, the arrangement of the electrical devices 100 in the package structure 200’ shown in FIG. 4 is different from that in the package structure 200 shown in FIG. 3J as another example for arranging the electrical devices 100.

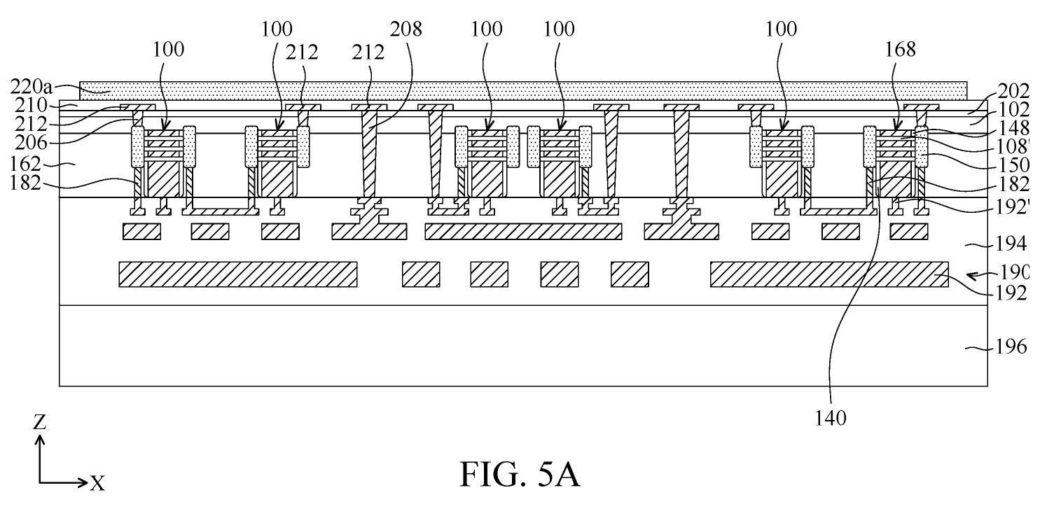

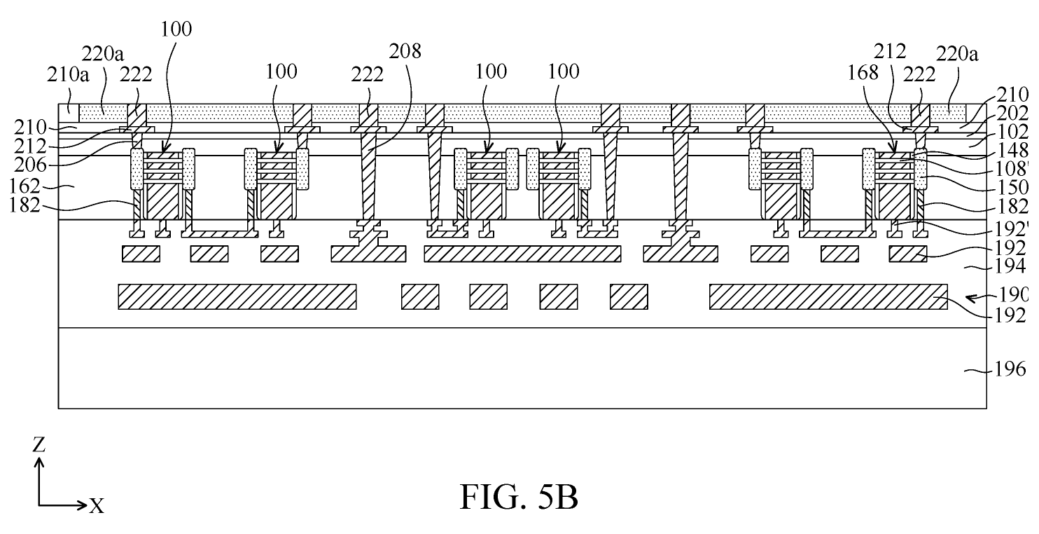

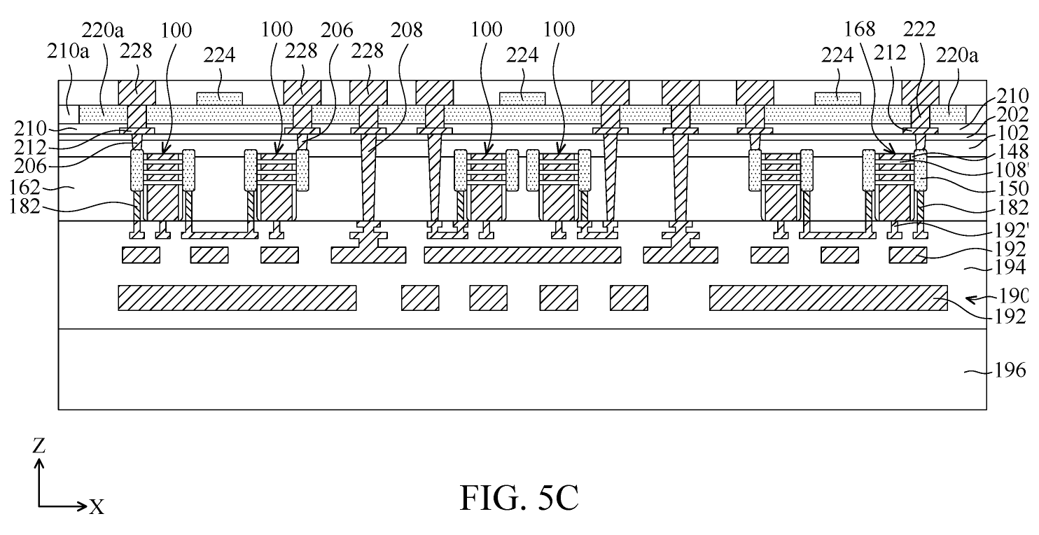

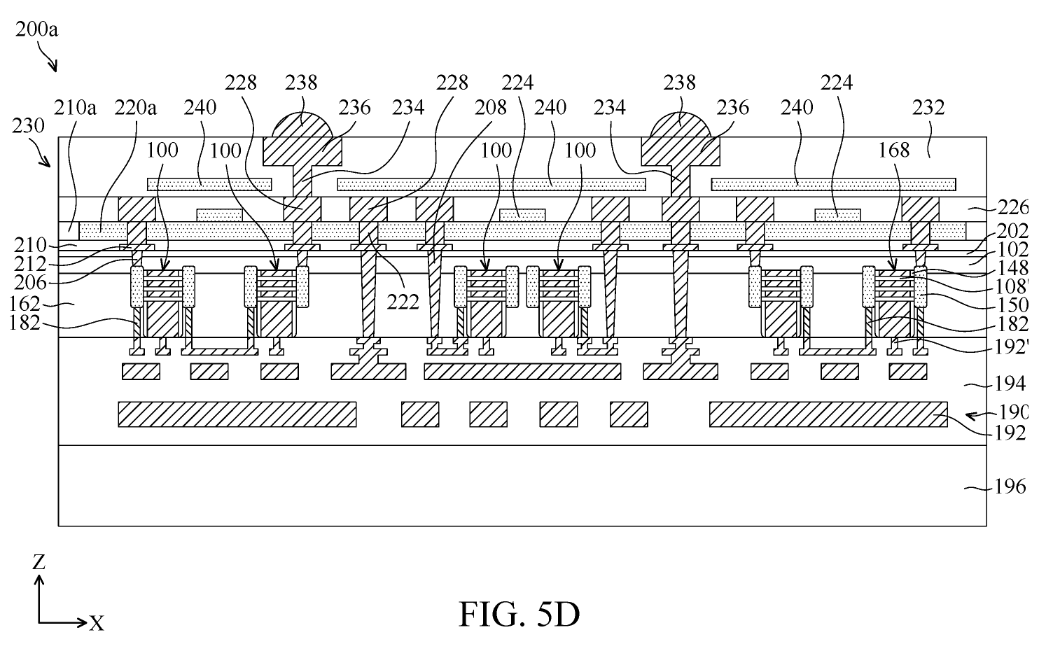

FIGS. 5A to 5D illustrate cross-sectional views of intermediate stages of manufacturing a package structure 200a in accordance with some embodiments. The package structure 200amay be similar to the package structure 200 described previously, except its waveguide layer is smaller than the substrate 102 in accordance with some embodiments. Processes and materials for forming the package structure 200a may be similar to, or the same as, those for forming the package structure 200 described previously and are not repeated herein.

More specifically, the processes shown in FIGS. 2A-1-2D-1,2A-2-2D-2, 2A-3-2D-3, and 3A-3F are performed, and a waveguide layer 220a is disposed or die to wafer bonding over the dielectric layer 210, as shown in FIG. 5A in accordance with some embodiments. In some embodiments, the waveguide layer 220ais a LiNbO₃ layer. The waveguide layer 220amay be the same as the waveguide layer 220 described above, except the waveguide layer 220a has a smaller size. In some embodiments, the width of the waveguide layer 220a is smaller than the width of the substrate 102 in both X direction and Y direction. Similar to the waveguide layer 220, the electrical devices 100 are fully inside the projection area of the waveguide layer 220a in the top view in accordance with some embodiments. That is, the electrical devices 100 vertically overlap the waveguide layer 220a (e.g. in the Z direction) in accordance with some embodiments.

After the waveguide layer 220a is disposed, an additional dielectric layer 210a is formed around the waveguide layer 220, and the conductive vias 222 are formed through the waveguide layer 220a and landing on the conductive structures 212, as shown in FIG. 5B in accordance with some embodiments. More specifically, the dielectric layer 210asurrounds the sidewalls of the waveguide layer 220a and covers the portions of the dielectric layer 210 not covered by the waveguide layer 220a in accordance with some embodiments. In some embodiments, the dielectric layer 210ais in direct contact with the top surface of the dielectric layer 210 and the sidewalls of the waveguide layer 220a. In some embodiments, the top surface of the dielectric layer 210a is substantially level with the top surface of the waveguide layer 220a.

In some embodiments, the dielectric layer 210ais made of a low k dielectric material having a k value lower than 7. In some embodiments, the dielectric layer 210a is made of SiO₂, SiN, SiCN, SiOC, SiOCN, or the like. The dielectric layer 210amay be formed by chemical vapor deposition (CVD), physical vapor deposition, (PVD), atomic layer deposition (ALD), or other applicable processes. After the dielectric layer 210a is formed, the conductive vias 222 are formed through the waveguide layer 220a and are electrically connected to the conductive structures 212.

Next, the processes shown in FIGS. 3H and 3I and described previously are performed to form waveguide features 224 and conductive structures 228 in the dielectric layer 226 over the waveguide layer 220a, as shown in FIG. 5C in accordance with some embodiments. Afterwards, the processes shown in FIG. 3J and described previously are performed to form the package structure 200a, as shown in FIG. 5D in accordance with some embodiments. Similar to the package structure 200, the package structure 200a includes both electrical devices 100 and optical devices (e.g. the waveguide layer 220aand the waveguide features 224 and 240) formed over a same wafer in accordance with some embodiments.

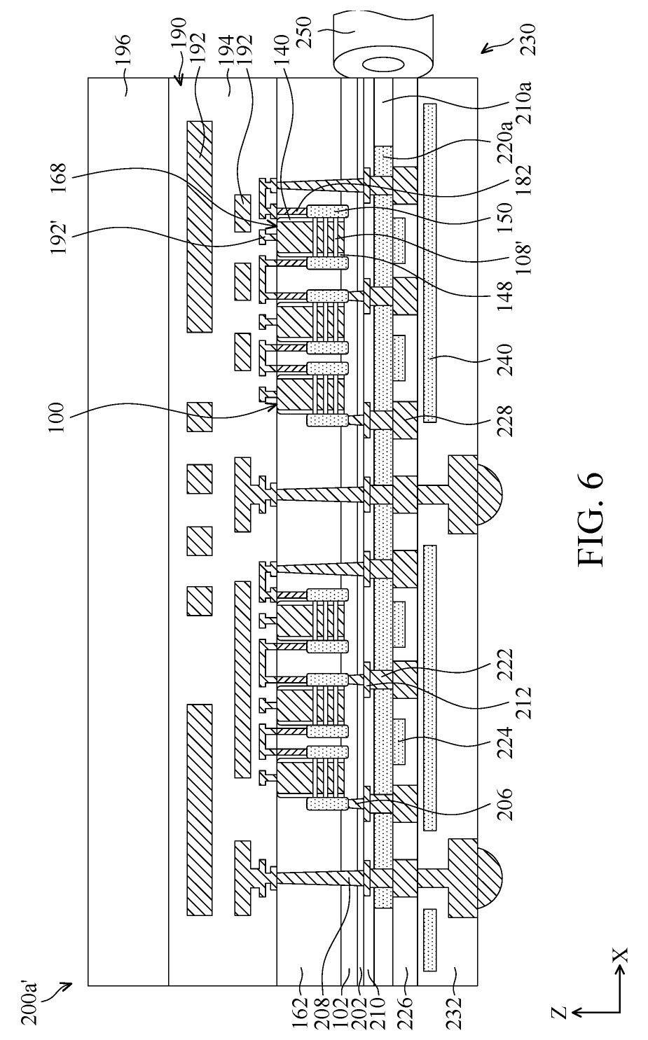

FIG. 6 illustrates a cross-sectional view of a package structure 200a’ in accordance with some embodiments. The package structure 200a’ may be similar to the package structure 200adescribed previously, except the optical fiber 250 is attached to the package structure 200a’ in accordance with some embodiments. Processes and materials for forming the package structure 200a’ may be similar to, or the same as, those for forming the package structure 200a described previously and are not repeated herein.

More specifically, the optical fiber 250 is attached to the sidewall of the waveguide layer 220a, as shown in FIG. 6 in accordance with some embodiments. In some embodiments, the optical fiber 250 laterally overlaps the waveguide layer 220a. In some embodiments, the optical fiber 250 also laterally overlaps the waveguide features 224. Similar to the package structure 200a, the package structure 200a’ includes both the electrical devices 100 and the optical devices (e.g. the waveguide layer 220aand the waveguide features 224 and 240) formed over a single wafer, so that the electrical and optical communication and computing may be improved. In addition, the arrangement of the electrical devices 100 in the package structure 200a’ shown in FIG. 6 is different from that in the package structure 200a shown in FIG. 5D as another example for arranging the electrical devices 100.

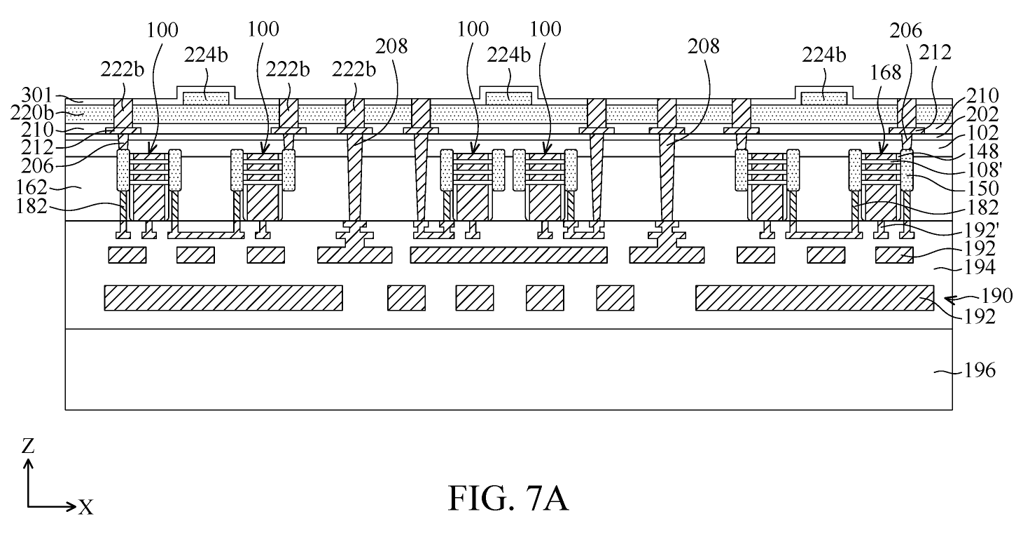

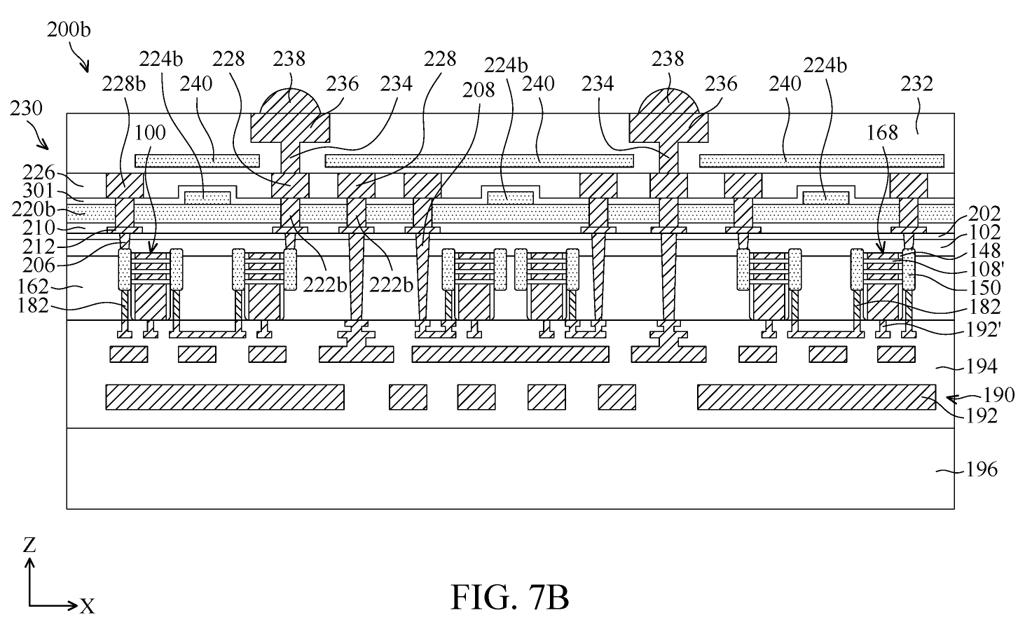

FIGS. 7A to 7B illustrate cross-sectional views of intermediate stages of manufacturing a package structure 200b in accordance with some embodiments. The package structure 200bmay be similar to the package structure 200 described previously, except an isolation layer 301 is formed over the waveguide layer and the waveguide features in accordance with some embodiments. Processes and materials for forming the package structure 200b may be similar to, or the same as, those for forming the package structure 200 described previously and are not repeated herein.

More specifically, the processes shown in FIGS. 2A-1-2D-1, 2A-2-2D-2,2A-3-2D-3, and 3A-3F are performed, and a waveguide layer 220b and waveguide features 224b are formed over the dielectric layer 210, and an isolation layer 301 is formed to cover the waveguide layer 220b and the waveguide features 224b, as shown in FIG. 7A in accordance with some embodiments. Afterwards, conductive vias 222bare formed through the isolation layer 301 and the waveguide layer 220b and are electrically connected to the conductive structures 212, as shown in FIG. 7A in accordance with some embodiments.

The isolation layer 301 is configured to separate the waveguide layer 220b and conductive structures 228b, so that light absorbed by the metal of the conductive features 228b may be reduced or prevented. Accordingly, the energy efficiency of the resulting package structure may be improved.

In some embodiments, the isolation layer 301 has a thickness in a range from about 10nm to about 200nm. In some embodiments, the isolation layer 301 is an oxide layer, such as SiO2. In some embodiments, the isolation layer 301 is made of a dielectric material having a k value lower than 7. The isolation layer 301 may be formed by chemical vapor deposition (CVD), physical vapor deposition, (PVD), atomic layer deposition (ALD), or other applicable processes.

After the isolation layer 301 is formed, the processes shown in FIGS. 3I to 3J and described previously are performed to form the package structure 200b, as shown in FIG. 7B in accordance with some embodiments. As shown in FIG. 7B, the isolation layer 301 is vertically sandwiched between the bottom surfaces of the conductive structures 228b and the top surface the waveguide layer 220b, so that the conductive structures 228b are vertically spaced apart (e.g. separated from) the waveguide layer 220bin accordance with some embodiments. Accordingly, the loss of light resulting from the absorption of the conductive structures 228b may be reduced. In addition, since the waveguide features 224b are covered by the isolation layer 301, the waveguide features 224b are separated from the dielectric layer 226 formed afterwards. In some embodiments, the isolation layer 301 vertically overlaps electrical devices 100.

The processes and materials for forming the waveguide layer 220b, the waveguide features 224b, the conductive vias 222b, and the conductive structures 228b are similar to, or the same as, those for forming the waveguide layer 220, the waveguide features 224, the conductive vias 222, and the conductive structures 228 described previously and are not repeated herein. Similar to the package structure 200, the package structure 200b includes both electrical devices 100 and optical devices (e.g. the waveguide layer 220band the waveguide features 224b and 240) formed over a same wafer in accordance with some embodiments.

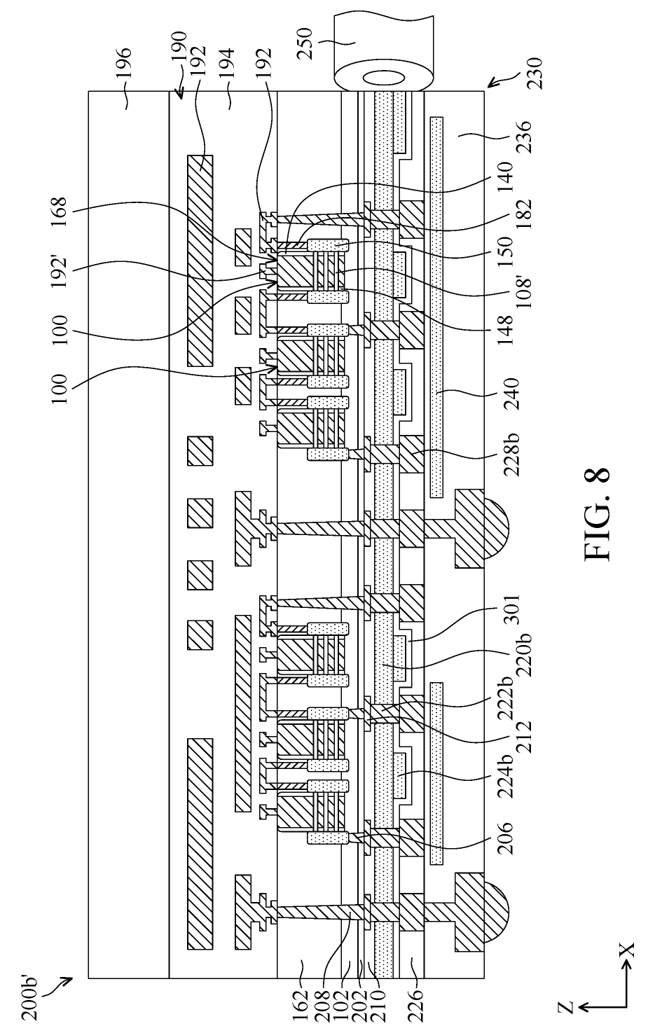

FIG. 8 illustrates a cross-sectional view of a package structure 200b’ in accordance with some embodiments. The package structure 200b’ may be similar to the package structure 200bdescribed previously, except the optical fiber 250 is attached to the package structure 200b’ in accordance with some embodiments. Processes and materials for forming the package structure 200b’ may be similar to, or the same as, those for forming the package structure 200b described previously and are not repeated herein.

More specifically, the optical fiber 250 is attached to the sidewall of the waveguide layer 220b, as shown in FIG. 8 in accordance with some embodiments. In some embodiments, the optical fiber 250 laterally overlaps the waveguide layer 220b. In some embodiments, the optical fiber 250 also laterally overlaps the waveguide features 224b. Similar to the package structure 200b, the package structures 200b’ includes both the electrical devices 100 and the optical devices (e.g. the waveguide layer 220band the waveguide features 224b and 240) formed over a single wafer, so that the electrical and optical communication and computing may be improved. In addition, the arrangement of the electrical devices 100 in the package structure 200b’ shown in FIG. 8 is different from that in the package structure 200b shown in FIG. 7B as another example for arranging the electrical devices 100.

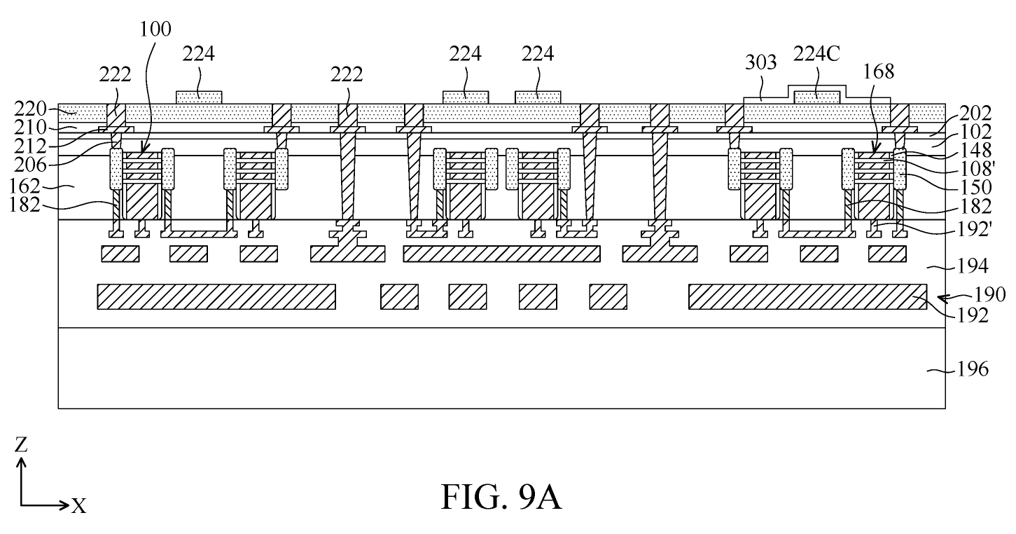

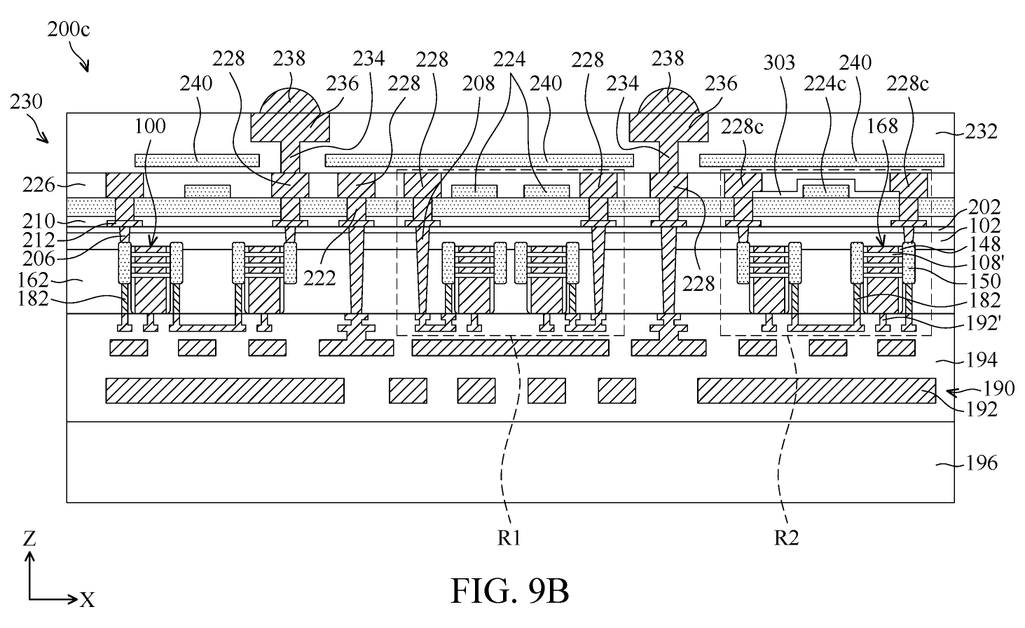

FIGS. 9A to 9B illustrate cross-sectional views of intermediate stages of manufacturing a package structure 200c in accordance with some embodiments. The package structure 200cmay be similar to the package structure 200 described previously, except an amorphous Si layer is formed over at least one of the waveguide features in accordance with some embodiments. Processes and materials for forming the package structure 200c may be similar to, or the same as, those for forming the package structure 200 described previously and are not repeated herein.

More specifically, the processes shown in FIGS. 2A-1-2D-1,2A-2-2D-2,2A-3-2D-3, and 3A-3H are performed, and an amorphous Si layer 303 is formed to cover at least one waveguide feature 224c of the waveguide features 224, as shown in FIG. 9A in accordance with some embodiments. Since light will be absorbed by the amorphous Si layer 303, electrical current in the region will be changed. That is, the change of the current may be detected as light pass by. Accordingly, the resulting structure may be used as a photo detector in the package structure 200c. In some embodiments, the amorphous Si layer 303 has a thickness in a range from about 50nm to about 300nm.

After the amorphous Si layer 303 is formed, the processes shown in FIGS. 3I to 3J and described previously are performed to form the package structure 200c, as shown in FIG. 9B in accordance with some embodiments. As shown in FIG. 9B, conductive structures 228c are partially formed over the amorphous Si layer 303 in accordance with some embodiments. That is, some portions of the amorphous Si layer 303 are vertically sandwiched between the bottom surfaces of the conductive structures 228c and the top surface the waveguide layer 220 in accordance with some embodiments. In addition, since the waveguide feature 224c is covered by the amorphous Si layer 303, the waveguide feature 224c is separated from the dielectric layer 226 formed afterwards. In some embodiments, the width of the amorphous Si layer 303 in the X direction is greater than the width of the waveguide feature 224c but is less than a width of the waveguide layer 220 in the X direction in the cross-sectional view

The processes and materials for forming the waveguide feature 224c and the conductive structures 228c are similar to, or the same as, those for forming the waveguide features 224 and the conductive structures 228 described previously and are not repeated herein. Similar to the package structure 200, the package structure 200c includes both electrical devices 100 and optical devices (e.g. the waveguide layer 220 and the waveguide features 224, 224c, and 240) formed over a same wafer in accordance with some embodiments. In addition, the package structure 200cincludes the Mach-Zehnder modulator phase shifter region R1 and a photo-detector region R2 in accordance with some embodiments.

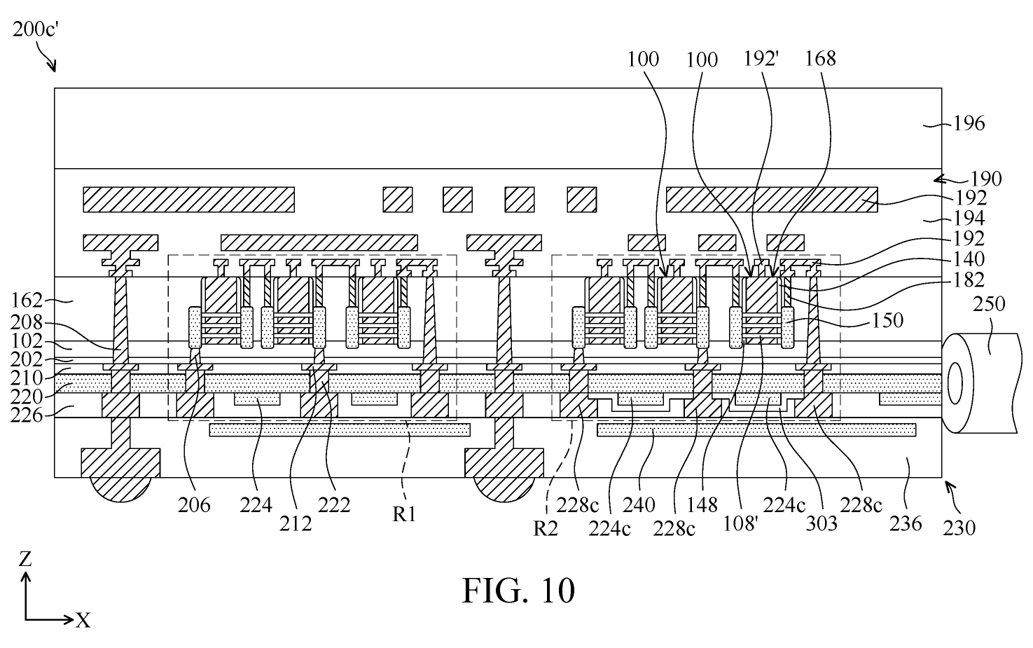

FIG. 10 illustrates a cross-sectional view of a package structure 200c’ in accordance with some embodiments. The package structure 200c’ may be similar to the package structure 200cdescribed previously, except the optical fiber 250 is attached to the package structure 200c’ in accordance with some embodiments. Processes and materials for forming the package structure 200c’ may be similar to, or the same as, those for forming the package structure 200c described previously and are not repeated herein. More specifically, the optical fiber 250 is attached to the sidewall of the waveguide layer 220, as shown in FIG. 10 in accordance with some embodiments. Similar to the package structure 200c, the package structures 200c’ includes both the electrical devices 100 and the optical devices (e.g. the waveguide layer 220 and the waveguide features 224, 224c, and 240) formed over a single wafer, so that the electrical and optical communication and computing may be improved. In addition, the arrangement of the electrical devices 100 in the package structure 200c’ shown in FIG. 10 is different from that in the package structure 200c shown in FIG. 9B as another example for arranging the electrical devices 100.

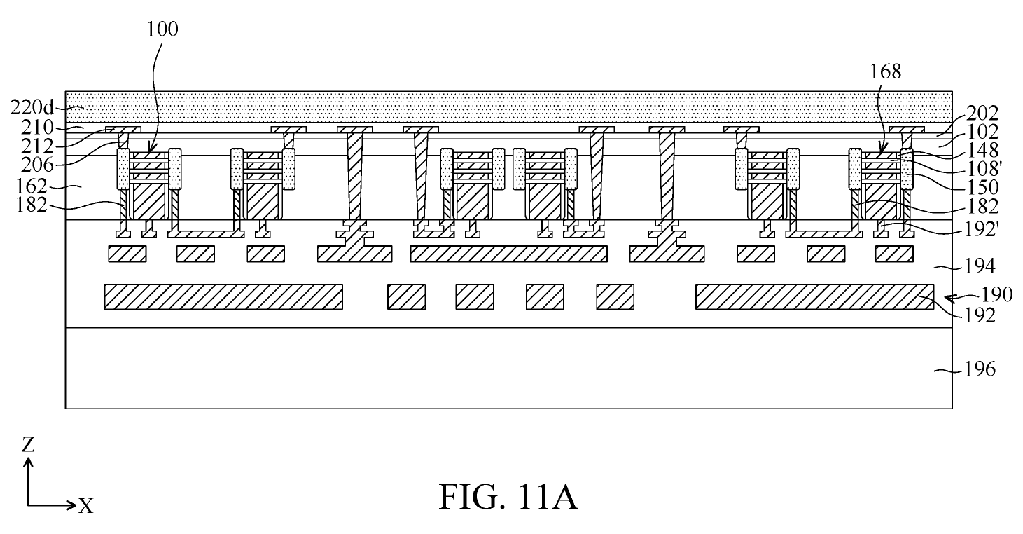

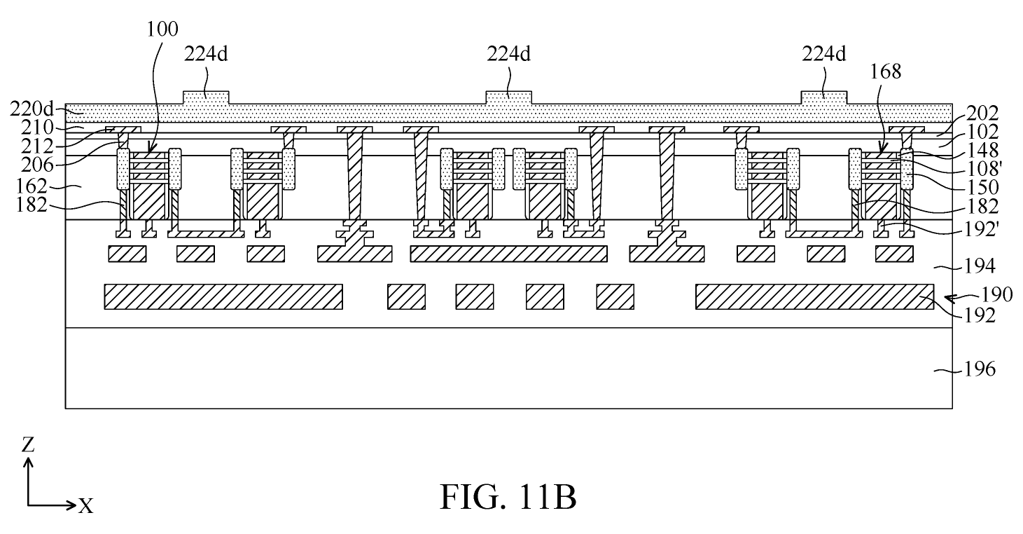

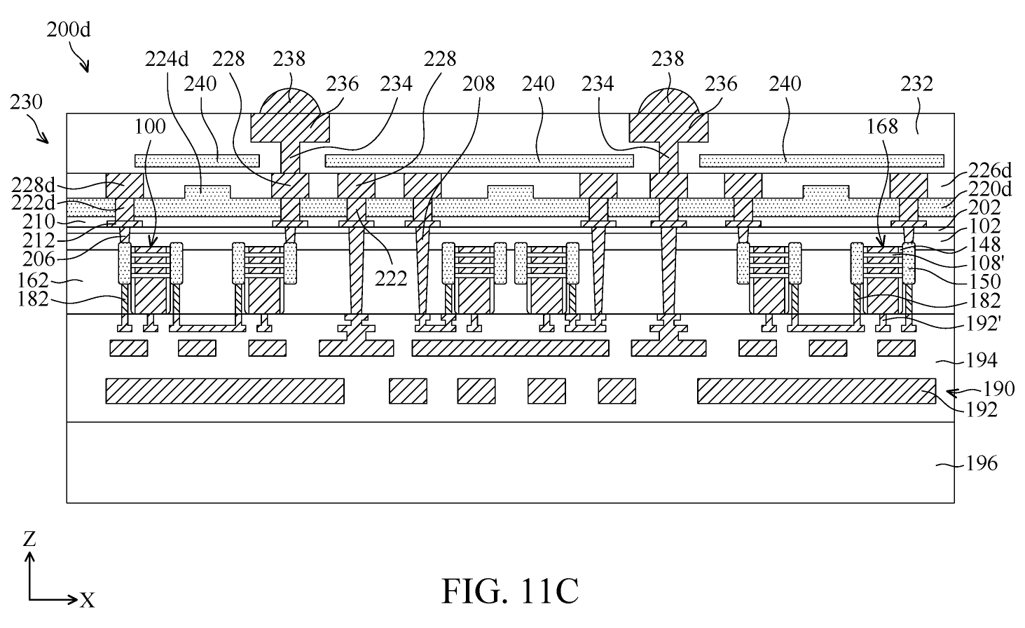

FIGS. 11A to 11C illustrate cross-sectional views of intermediate stages of manufacturing a package structure 200d in accordance with some embodiments. The package structure 200d may be similar to the package structure 200 described previously, except its waveguide features are formed of it waveguide layer in accordance with some embodiments. Processes and materials for forming the package structure 200d may be similar to, or the same as, those for forming the package structure 200 described previously and are not repeated herein.

More specifically, the processes shown in FIGS. 2A-1-2D-1, 2A-2, -2D-2, 2A-3-2D-3, and 3A-3F are performed, and a waveguide layer 220d is disposed over the dielectric layer 210, as shown in FIG. 11A in accordance with some embodiments. In some embodiments, the waveguide layer 220d is a LiNbO3 layer. In some embodiments, the thickness of the waveguide layer 220d is in a range from about 300nm to about 800nm.

After the waveguide layer 220d is disposed, the upper portion of the waveguide layer 220d is patterned to form waveguide features 224d, as shown in FIG. 11B in accordance with some embodiments. Since the waveguide features 224dare formed by patterning the waveguide layer 220d, the waveguide layer 220d and the waveguide features 224d are made of the same material, such as LiNbO3 in accordance with some embodiments. Since the waveguide layer 220d and the waveguide features 224d are made of the same material, the loss of light during light transportation may be reduced. In addition, there is no interface between the waveguide layer 220d and the waveguide features 224d in accordance with some embodiments. In some embodiments, the waveguide features 224dhave a thickness in a range from about 100nm to about 800nm in Z direction.

Next, conductive vias 222d, conductive structures 228d and a dielectric layer 226d are formed, and the processes shown in FIG. 3J and described previously are performed to form the package structure 200d, as shown in FIG. 11C in accordance with some embodiments. More specifically, the conductive vias 222dare formed through the waveguide layer 220d, and the dielectric layer 226d is formed over the waveguide layer 220d and around the waveguide features 224d in accordance with some embodiments. In addition, the conductive structures 228dare formed through the dielectric layer 226d in accordance with some embodiments.

Similar to the package structure 200, the package structure 200d includes both electrical devices 100 and optical devices (e.g. the waveguide layer 220d and the waveguide features 224d and 240) formed over a same wafer in accordance with some embodiments. Processes and materials for forming the waveguide layer 220d, the dielectric layer 226d, the conductive vias 222d, and the conductive structures 228d may be similar to, or the same as, those for forming the waveguide layer 220, the dielectric layer 226, the conductive vias 222, and the conductive structures 228 described previously and are not repeated herein.

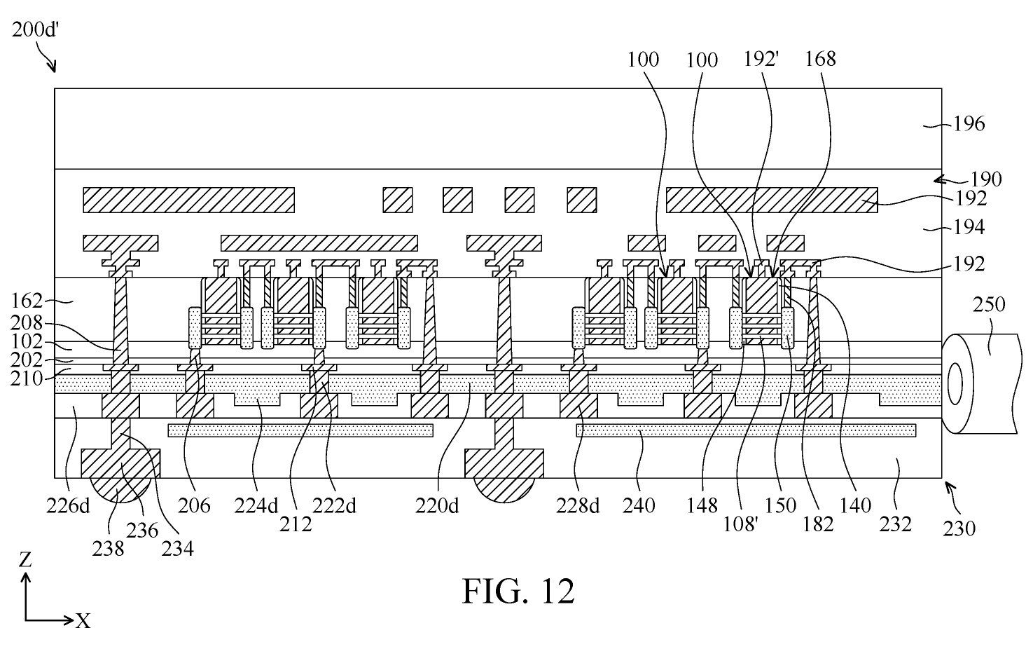

FIG. 12 illustrates a cross-sectional view of a package structure 200d’ in accordance with some embodiments. The package structure 200d’ may be similar to the package structure 200ddescribed previously, except the optical fiber 250 is attached to the package structure 200d’ in accordance with some embodiments. Processes and materials for forming the package structure 200d’ may be similar to, or the same as, those for forming the package structure 200d described previously and are not repeated herein.

More specifically, the optical fiber 250 is attached to the sidewall of the waveguide layer 220d, as shown in FIG. 12 in accordance with some embodiments. In some embodiments, the optical fiber 250 laterally overlaps the waveguide layer 220d. In some embodiments, the optical fiber 250 also laterally overlaps the waveguide features 224d. Similar to the package structure 200d, the package structures 200d’ includes both the electrical devices 100 and the optical devices (e.g. the waveguide layer 220dand the waveguide features 224d and 240) formed over a single wafer, so that the electrical and optical communication and computing may be improved. In addition, the arrangement of the electrical devices 100 in the package structure 200d’ shown in FIG. 12 is different from that in the package structure 200d shown in FIG. 11C as another example for arranging the electrical devices 100.

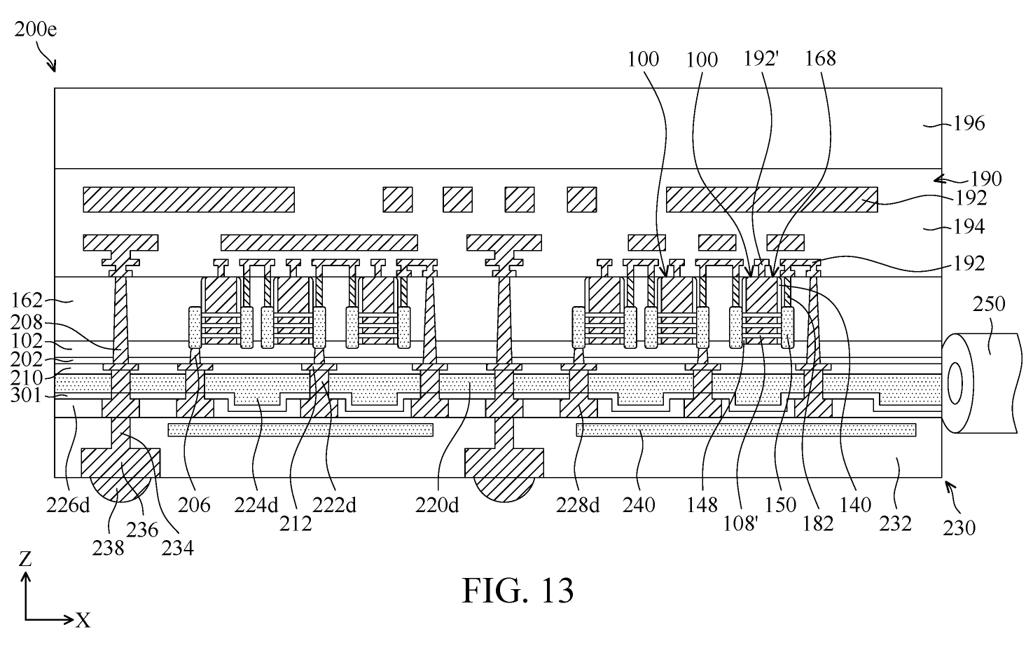

FIG. 13 illustrates a cross-sectional view of a package structure 200e in accordance with some embodiments. The package structure 200emay be similar to the package structure 200d’ described previously, except the isolation layer 301 is formed in accordance with some embodiments. More specifically, the isolation layer 301 shown in FIGS. 7A, 7B, and 8 is applied to the package structure 200d’ shown in FIG. 12 in accordance with some embodiments.

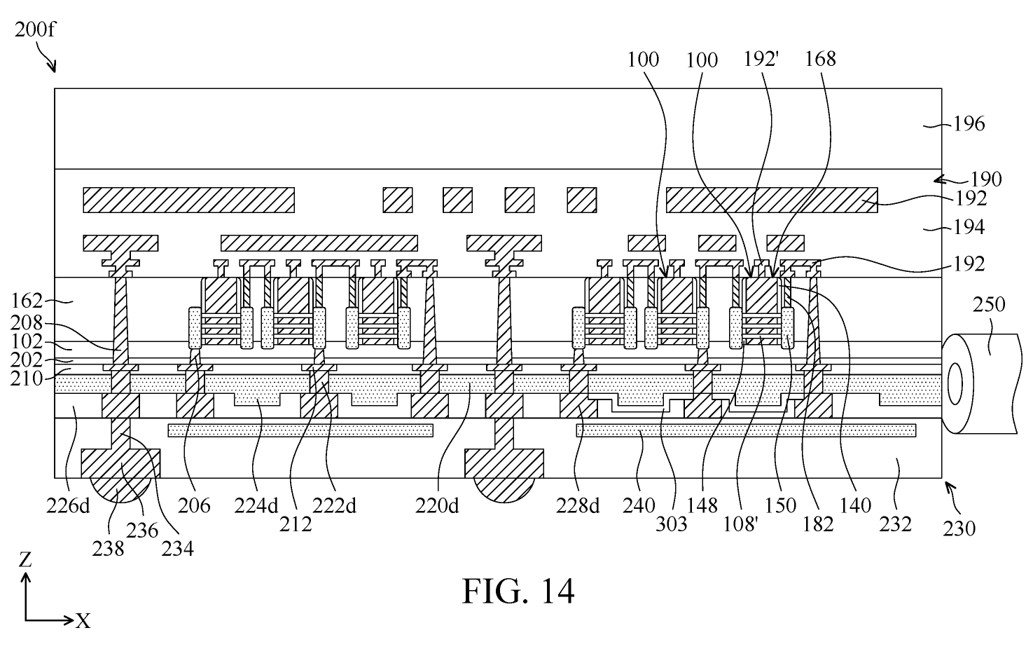

FIG. 14 illustrates a cross-sectional view of a package structure 200f in accordance with some embodiments. The package structure 200fmay be similar to the package structure 200d’ described previously, except the amorphous Si layer 303 is formed in accordance with some embodiments. More specifically, the amorphous Si layer 303 shown in FIGS. 9A, 9B, and 10 is applied to the package structure 200d’ shown in FIG. 12 in accordance with some embodiments.

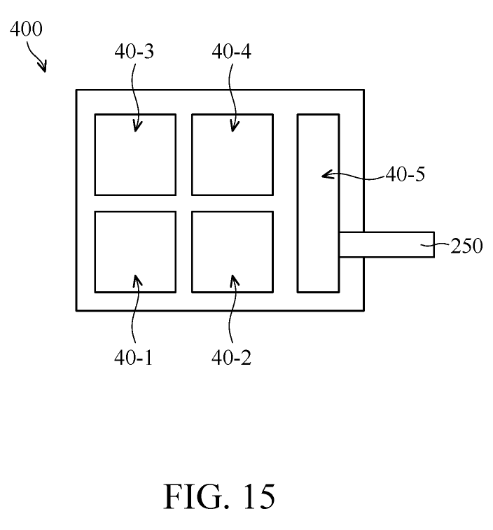

The package structures described above may be cut (i.e. diced) into numbers of chip structures, and each of the chip structures includes both electrical devices 100 and optical devices. The chip structures may be further bonded with other elements. For example, the chips structure may be bonded to an interposer structure. FIG. 15 illustrates a diagrammatic top view of a package structure 400 in accordance with some embodiments. In some embodiments, the package structure 400 includes chip structures 40-1, 40-2, 40-3, 40-4, and 40-5. In some embodiments, the chip structures 40-1, 40-2, 40-3, and 40-4 are formed by cutting the package structure 200, 200’, 200a, 200a’, 200b, 200b’, 200c, 200c’ 200d, 200d’, 200e, or 200f. In some embodiments, the chip structures 40-1, 40-2, 40-3, and 40-4 are processor chips structures, and the chip structure 40-5 is an I/O chip structure. In some embodiments, the chip structures 40-1, 40-2, 40-3, and 40-4 have the same structure. In some embodiments, the chip structures 40-1, 40-2, 40-3, and 40-4 include at least two kinds of chip structures formed by cutting the package structure 200, 200’, 200a, 200a’, 200b, 200b’, 200c, 200c’ 200d, 200d’, 200e, or 200f.

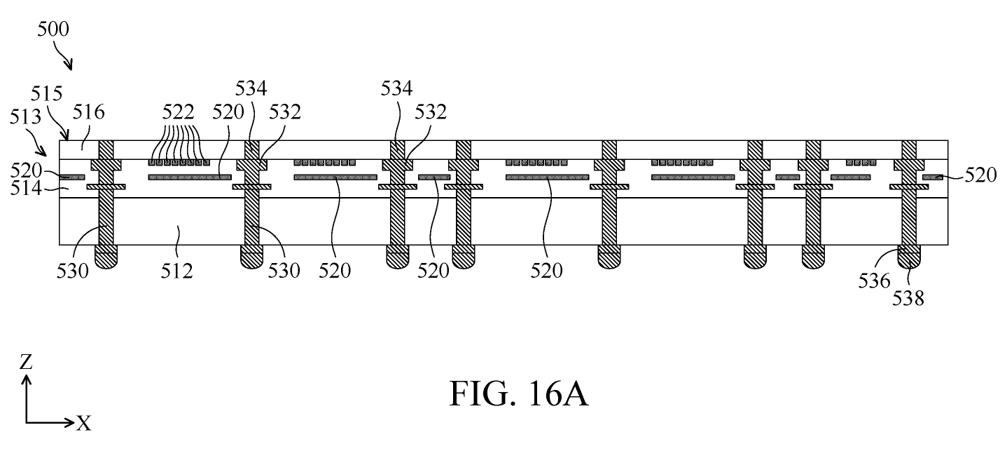

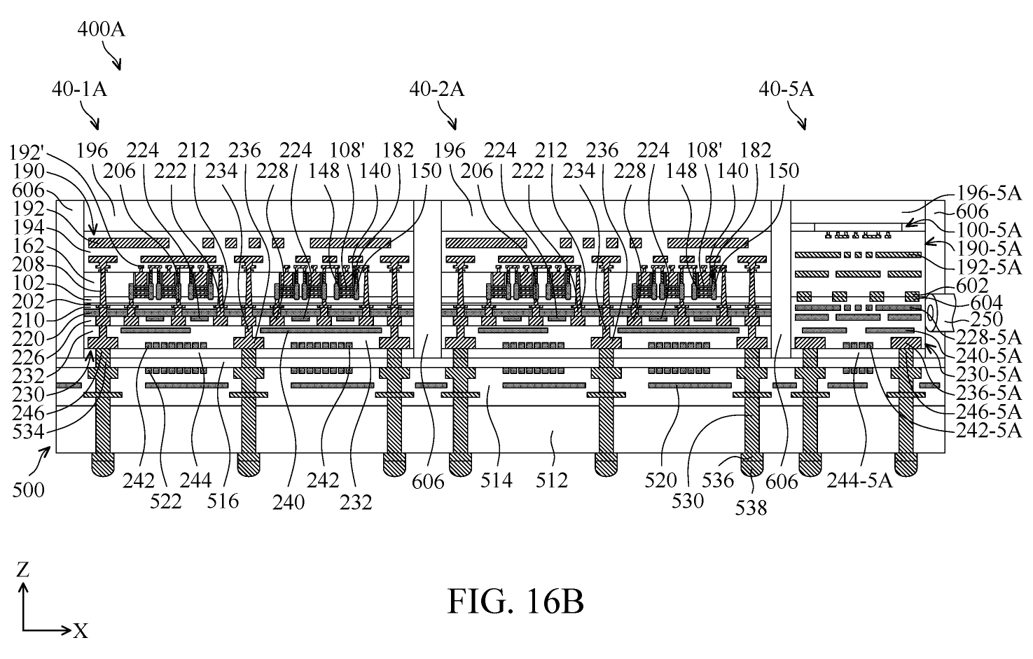

FIGS. 16A to 16B illustrate cross-sectional representations of various stages of forming a package structure 400A in accordance with some embodiments. The package structure 400A may have the top view as shown in FIG. 15.

First, an interposer structure 500 is formed, as shown in FIG. 16A in accordance with some embodiments. The interposer structure 500 may be an optical interposer structure including both conductive structures and optical elements formed therein. That is, the interposer structure 500 may receive various signals, including electrical signals or optical signals, translate the signals into optical signals, route the optical signals, translate the optical signals into electrical signals, and send the electrical signals to the designated components. In some embodiments, the interposer structure 500 includes an interposer substrate 512, an optical structure 513, and a bonding structure 515. In some embodiments, the interposer substrate 512 is a Si substrate, such as a Si wafer.

In some embodiments, the optical structure 513 includes a dielectric layer 514 formed over the interposer substrate 512 and optical elements formed in the dielectric layer 514. In some embodiments, the dielectric layer 514 includes a low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

In some embodiments, optical elements, including waveguide features 520 and grating couplers 522, are formed in the dielectric layer 514. The waveguide features 520 and grating couplers 522 are configured to receive and redirect incoming, off-plane signals from the optical fiber 250 (shown in FIG. 16B). The waveguide features 520 and the grating couplers 522 may be formed of the material for forming the waveguide features 224 and 240 described previously.

In addition, interposer-through-vias 530 are formed through the interposer substrate 512 in accordance with some embodiments. The interposer-through-vias 530 penetrate through the interposer substrate 512 to provide a quick passage of power, data and ground through the interposer substrate 512. In some embodiments, the interposer-through-vias 530 are spaced apart from the waveguide features 520 and grating couplers 522. A liner and/or a barrier layer (not shown) may be formed around the interposer-through-vias 530. For example, the liner layer may be made of an insulating material, such as oxides, nitrides, or other applicable material, and the diffusion barrier layer may be made of tantalum (Ta), tantalum nitride (TaN), titanium (Ti), titanium nitride (TiN), cobalt tungsten (CoW), or other applicable material.

In addition, conductive structures 532 are formed over and electrically connected to the interposer-through-vias 530 in accordance with some embodiments. In some embodiments, the interposer-through-vias 530 and the conductive conductive structures 532 are made of conductive materials, such as copper (Cu), copper alloy, aluminum (Al), aluminum alloys, combinations thereof or another applicable material.

In some embodiments, the bonding structure 515 includes a bonding layer 516 and conductive bonding pads 534 formed in the bonding layer 516, as shown in FIG. 16A. In some embodiments, the bonding layer 516 is made of silicon oxide. In some embodiments, the bonding layer 516 is made of a polymer, such as benzocyclobutene (BCB) polymer, polyimide (PI), or polybenzoxazole (PBO), or other applicable material. In some embodiments, the conductive bonding pads 534 are made of conductive materials, such as copper (Cu), copper alloy, aluminum (Al), aluminum alloy, or another applicable material.

In some embodiments, UBM layers 536 are formed below the interposer-through-vias 530, and the conductive connectors 538 are formed attached to the UBM layers 536, as shown in FIG. 16A. The conductive connectors 538 are electrically connected to the conductive structures 532 through the interposer-through-vias 530 in accordance with some embodiments.

In some embodiments, the UBM layers 536 are made of titanium (Ti), titanium nitride (TiN), tantalum (Ta), tantalum nitride (TaN), tungsten (W), titanium tungsten (TiW), nickel (Ni), gold (Au), chrome (Cr), copper (Cu), copper alloy, other applicable material, or a combination thereof. In some embodiments, the conductive connectors 538 are made of copper, a copper alloy, or other applicable material. In some embodiments, the UBM layers 536 and conductive connectors 538 are formed by chemical vapor deposition (CVD), physical vapor deposition (PVD), plasma enhanced CVD (PECVD), plasma enhanced physical vapor deposition (PEPVD), atomic layer deposition (ALD), or another applicable deposition processes.

Afterwards, the chip structures 40-1A, 40-2A, and 40-5A and the optical fiber 250 are disposed over the interposer structure 500, as shown in FIG. 16B in accordance with some embodiments. The chip structures 40-1A, 40-2A, and 40-5A may have the layout the same as that of the chip structures 40-1, 40-2, and 40-5 shown in FIG. 15 repectively. In addition, two more chip structures having the same, or similar structures, with the chip structures 40-1A and 40-2A may have the same layout with the chip structures 40-3 and 40-4 shown in FIG. 15, although not shown in FIG. 16B.

The chip structures 40-1A and 40-2A may be formed by performing the processes shown in FIGS. 1 to 3I described previously. In addition, grating couplers 242 are formed in the dielectric layer 232 in accordance with some embodiments. Furthermore, instead of the conductive bumps 238, a bonding layer 244 is formed to cover the interconnect structure 230, and the conductive bonding pads 246 are formed in the bonding layer 244, as shown in FIG. 16B in accordance with some embodiments. Processes and materials for forming the bonding layer 244 and the conductive bonding pads 246 may be similar to, or the same as, those for forming the bonding layer 516 and the conductive bonding pads 534 and are not repeated herein.

After the bonding layer 244 and the conductive bonding pads 246 are formed, the package structure is diced to form the chip structures 40-1A and 40-2A, and the chip structures 40-1A and 40-2A are bonded to the interposer structure 500 through a hybrid bonding process, as shown in FIG. 16B in accordance with some embodiments. More specifically, the hybrid bonding involves at least two types of bonding, including metal-to-metal bonding and non-metal-to-non-metal bonding. In some embodiments, the bonding layer 516 is bonded to the bonding layer 244, and the conductive bonding pads 534 are bonded to the conductive bonding pads 246 by the applying pressure and heat. In addition, the grating couplers 242 substantially aligned with the grating couplers 522 in the Z direction in the cross-sectional view in accordance with some embodiments. As described previously, each of the chip structures 40-1A and 40-2A includes both the electrical devices 100 and the optical devices (e.g. waveguide layer 220 and waveguide features 224, 240, and 242).

The chip structure 40-5A may be an input/output (I/O) chip that is designed to work in conjunction with the chip structures 40-1A and 40-2A. For example, the chip structure 40-5A may work to control signals entering and leaving the chip structures 40-1A and 40-2A and also coordinating with signals entering and leaving the interposer structure 500 through the optical fiber 250.

In some embodiments, the chip structure 40-5A also includes electrical devices and the optical devices, but instead of forming the electrical devices and the optical devices in the same wafer as described above, they are formed at separated wafers and bonded together afterwards. The chip structure 40-5A may be formed by forming a first wafer having an electrical device regions 100-5A and an interconnect structure 190-5A formed over the front side of the electrical device regions 100-5A. In some embodiments, the electrical device regions 100-5A includes electrical devices 100 shown in FIGS. 2D-1, 2D-2, and 2D-3. The interconnect structure 190-5A includes conductive structures 192-5A connected to the front sides of the electrical devices 100 in the electrical device regions 100-5A. In addition, conductive bonding pads 602 are formed over the top portions of the interconnect structure 190-5A.

A second wafer having optical devices may be separately formed. For example, the second wafer may include an interconnect structure 230-5A with metal layers 236-5A, waveguide features 240-5A, and grating couplers 242-5A formed therein. In addition, conductive bonding pads 604 are formed over the top portions of the interconnect structure 230-5A. Afterwards, the first wafer and the second wafer are bonded through the conductive bonding pad 602 and 604, using a carrier substrate 196-5A as a support, to form a package structure, and the package structure is diced to form the chip structure 40-5A.

The chip structure 40-5A may be bonded to the interposer structure 500 in a similar fashion as the chip structures 40-1A and 40-2A. More specifically, the chip structure 40-5A may be bonded to the interposer structure 500 through a bonding layer 244-5A and conductive bonding pads 246-5A, as shown in FIG. 16B in accordance with some embodiments. The processes and materials for forming the interconnect structure 190-5A, the conductive structures 192-5A, the interconnect structure 230-5A, the metal layers 236-5A, the waveguide features 240-5A, the grating couplers 242-5A, the carrier substrate 196-5A, the bonding layer 244-5A, and the conductive bonding pads 246-5A, 602, and 604 may be similar to, or the same as, those for forming the interconnect structure 190, the conductive structures 192, the interconnect structure 230, the metal layer 236, the waveguide features 240, the grating couplers 242, the carrier substrate 196, the bonding layer 244, and the conductive bonding pads 246 described previously and are not repeated herein.

After the chip structures 40-1A, 40-2A, and 40-5A are bonded to the interposer structure 500, an encapsulant 606 may be formed on and around the chip structures 40-1A, 40-2A, and 40-5A and the optical fiber 250 in accordance with some embodiments. In some embodiments, the encapsulant 606 is a molding compound, such as epoxy, or the like. The encapsulant 606 may be applied by compression molding, transfer molding, or the like.

After the encapsulant 606 is applied, a planarization process may be performed on the encapsulant 606 until the top surfaces of the chip structures 40-1A, 40-2A, and 40-5A are exposed, as shown in FIG. 16B in accordance with some embodiments. In some embodiments, the top surfaces of the encapsulant 606 and the chip structures 40-1A, 40-2A, and 40-5A are substantially level with each other after the planarization process. The planarization process may be, for example, a chemical-mechanical polish (CMP), a grinding process, or the like. In some embodiments, the planarization may be omitted.

As described previously, the electrical devices 100 and the optical devices in the chip structures 40-1A and 40-2A are formed in the same wafer without using additional bonding structures, such as bonding pads or bumps. In addition, backside conductive structures are formed to electrically connected to the backside of the electrical devices 100, so that the interconnect structure 190 and the optical devices, such as the waveguide layer 220, can be formed at opposite sides of the electrical devices 100 in accordance with some embodiments. Accordingly, the electrical routing of the chip structures 40-1A and 40-2A may be improved.

On the other hand, the interconnect structure 190-5A and the optical device, such as the waveguide features 240-5A are both formed over the front side of the electrical device 100 (not shown in FIG. 16B) in the electrical device region 100-5A in the chip structure 40-5A in accordance with some embodiments. The chip structure 40-5A may therefore have a higher voltage tolerance and therefore may be used as an I/O chip in the package structure 400A in accordance with some embodiments.

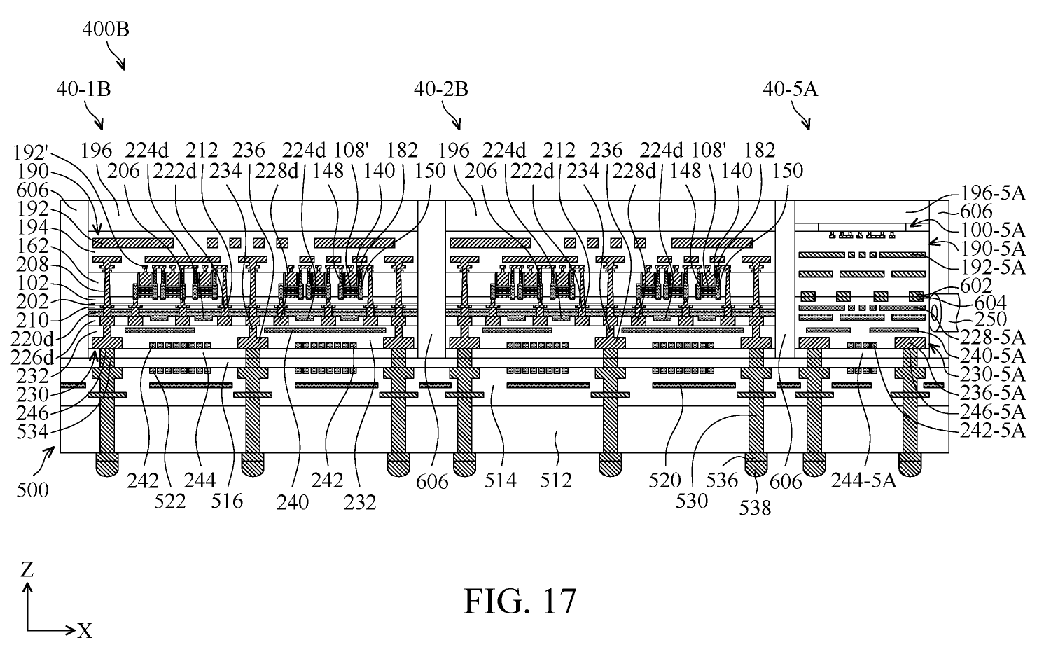

FIGS. 17-21 illustrate cross-sectional view of package structures 400B, 400C, 400D, 400E, and 400F in accordance with some embodiments. Similar to the package structure 400A, the package structures 400B, 400C, 400D, 400E, and 400D also have the same layout as shown in FIG. 15 in accordance with some embodiments.

FIG. 17 illustrates the cross-sectional view of the package structure 400B in accordance with some embodiments. The package structure 400Bmay be similar to the package structure 400A described previously, except the waveguide features are formed from patterning the waveguide layer in accordance with some embodiments. More specifically, chip structures 40-1B and 40-2B are formed by cutting the package structure 200d shown in FIG. 11C, except the conductive bumps 238 are replaced by the bonding layer 244 and the conductive bonding pads 246.

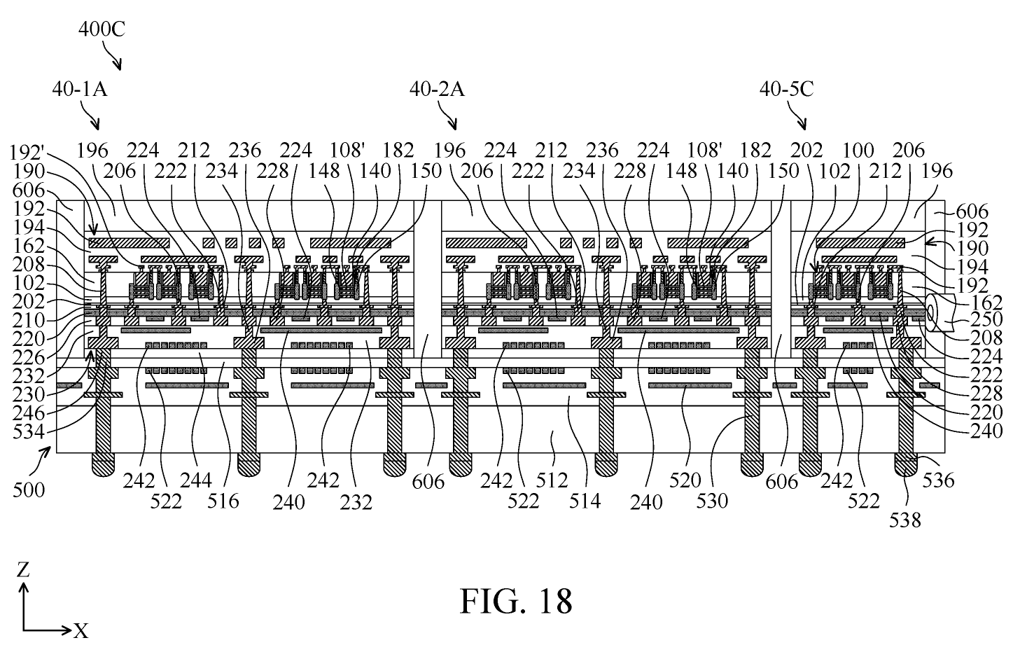

FIG. 18 illustrates the cross-sectional view of the package structure 400C in accordance with some embodiments. The package structure 400C may be similar to the package structure 400A described previously, except the chip structure 40-5A is replaced by a chip structure 40-5C in accordance with some embodiments. More specifically, the chip structure 40-5C may also be used as an I/O chip structure, but the chip structure 40-5C has the structure similar to that of the chip structures 40-1A and 40-2A. That is, the backside conductive structure are formed, and the interconnect structure 190 and the optical devices, such as waveguide layer 220, are formed at opposite sides of the electrical devices 100, as shown in FIG. 18 in accordance with some embodiments. The waveguide layer 220 in the chip structure 40-5C may be controlled by a relatively low voltage, and therefore the structure may be used in devices requiring lower voltage for its I/O devices.

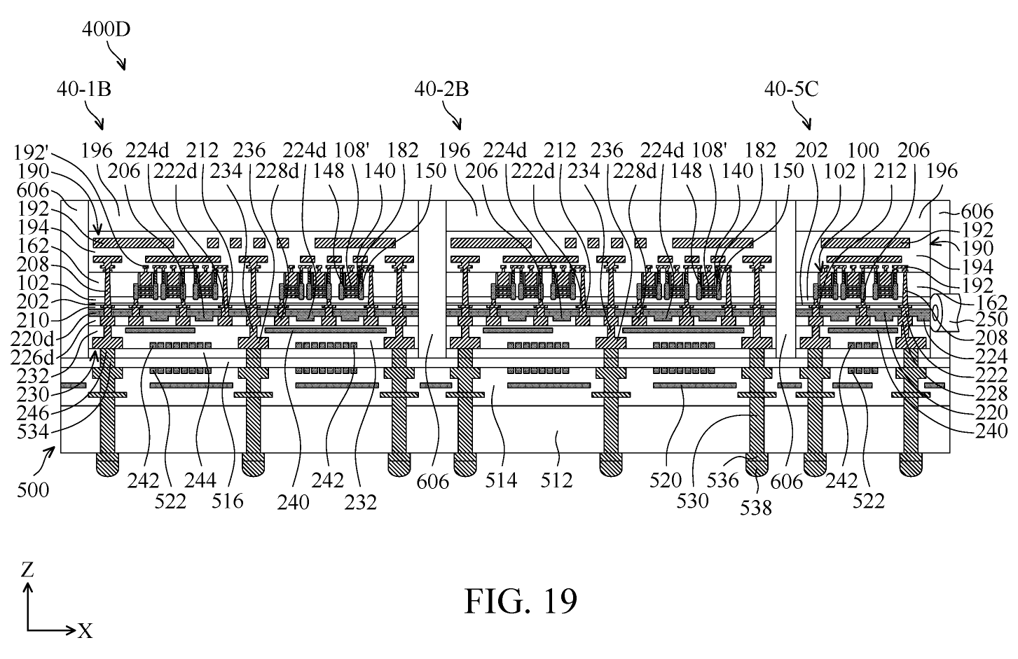

FIG. 19 illustrates the cross-sectional view of the package structure 400D in accordance with some embodiments. The package structure 400D may be similar to the package structure 400B described previously, except the chip structure 40-5A is replaced by the chip structure 40-5C in accordance with some embodiments.

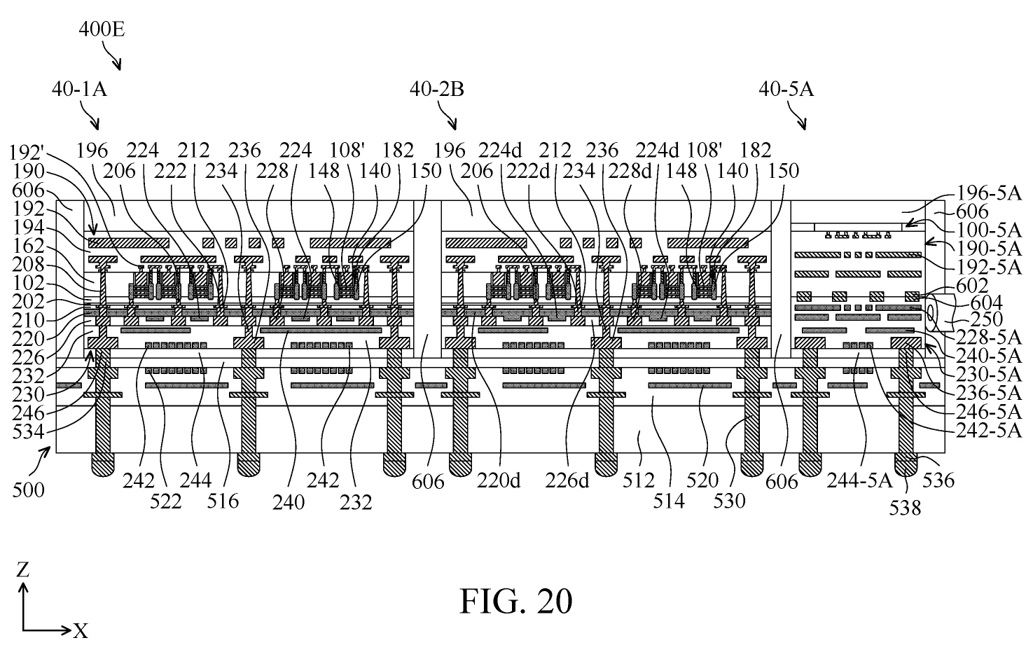

FIG. 20 illustrates the cross-sectional view of the package structure 400E in accordance with some embodiments. The package structure 400E may be similar to the package structure 400A described previously, except the chip structure 40-2A is replaced by the chip structure 40-2B in accordance with some embodiments. That is, the chip structures 40-1A and 40-2B have different structures in accordance with some embodiments.

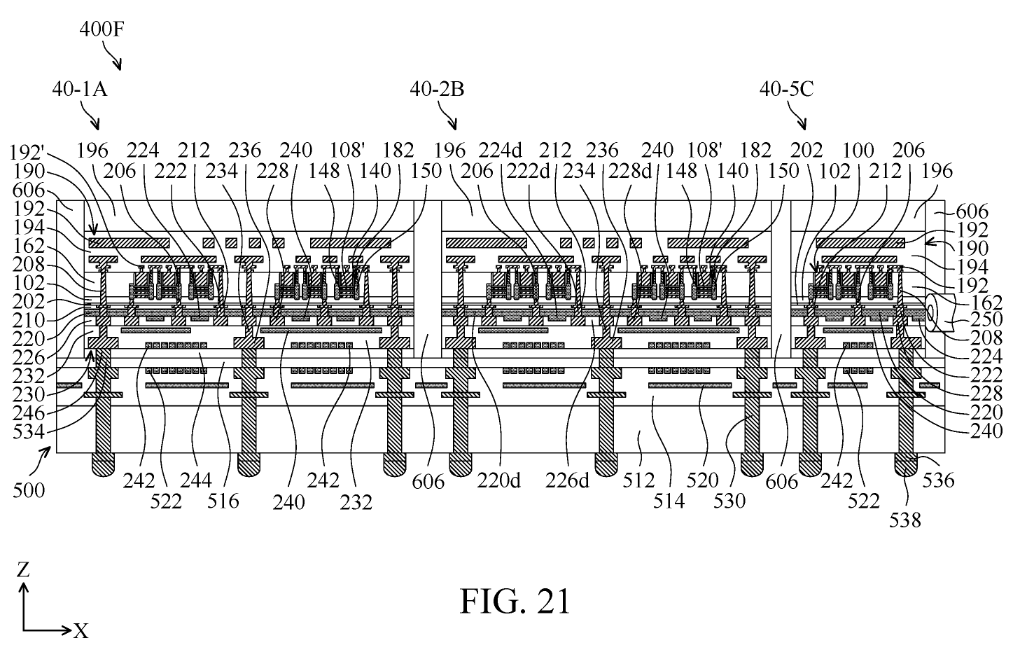

FIG. 21 illustrates the cross-sectional view of the package structure 400F in accordance with some embodiments. The package structure 400F may be similar to the package structure 400E described previously, except the chip structure 40-5A is replaced by the chip structure 40-5C in accordance with some embodiments.

As described above, if the electrical devices and optical devices are formed at separated chips and bonded together afterwards, the routing for optical signals and electrical signals may be relatively long and the power consumption may be less efficiency. Accordingly, in some embodiments of the present application, the electrical devices 100 and the optical devices (e.g. the waveguide layers 220, 220a, 220b, and 220d) are integrated at the same wafer/chip structure. More specifically, backside power delivery network is applied to the electrical devices 100, so that the signals may be transported from the front side of the electrical devices 100 to the backside of the electrical devices 100. Therefore, the routing in the resulting chip structures may be shortened, and the speed and the power efficiency may be improved.

In addition, the waveguide layer (e.g. the waveguide layers 220, 220a, 220b, and 220d) may be a LiNbO₃ layer in accordance with some embodiments. The LiNbO₃ layer may have a lower loss of light, compared to other waveguide materials such as SiN, and may provide improved optical communication and computing for the package structures.

It should be appreciated that the elements shown in the package structures 200, 200’, 200a, 200a’, 200b, 200b’, 200c, 200c’, 200d, 200d’, 200e, 200f, 400, 400A, 400B, 400C, 400D, 400E, and 400F may be combined and/or exchanged. For example, the package structure may have the layout shown in FIG. 15 with various chip structures shown in FIGS. 1 to 14.

In addition, it should be noted that same elements in FIGS. 1 to 21 may be designated by the same numerals and may include materials that are the same or similar and may be formed by processes that are the same or similar; therefore such redundant details are omitted in the interests of brevity. In addition, although FIGS. 1 to 21 are described in relation to the method, it will be appreciated that the structures disclosed in FIGS. 1 to 21 are not limited to the method but may stand alone as structures independent of the method. Similarly, the methods shown in FIGS. 1 to 21 are not limited to the disclosed structures but may stand alone independent of the structures. Furthermore, the channel structures (e.g. the nanostructures) described above may include nanowires, nanosheets, or other applicable nanostructures in accordance with some embodiments.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming package structures may be provided. The package structure may include forming an electrical device over a substrate and forming an interconnect structure over the front side of the electric device. Afterwards, backside through vias may be formed at and connected to the backside of the electrical device, and optical devices may be formed over the backside through vias. That is, by forming the backside through vias, the routing between the electrical devices and the optical devices may be shorted, and the speed and power consumption of the resulting package structure may be improved.

In some embodiments, a method for manufacturing a package structure is provided. The method includes forming electrical devices over a substrate and forming an interconnect structure over front sides of the electrical devices. The method also includes thinning the substrate and forming backside through vias connecting to backsides of the electrical devices. The method also includes attaching a waveguide layer over backsides of the electrical devices and forming conductive vias through the waveguide layer and electrically connected to the backside through vias.

In some embodiments, a method for manufacturing a package structure is provided. The method includes forming a transistor over a first side of a semiconductor substrate and forming a first interconnect structure over a first side of the transistor. The method also includes at least partially removing the semiconductor substrate from a second side of the semiconductor substrate and forming a backside through via landing on a second side of the transistor. The method also includes disposing a waveguide layer over the backside through via and forming first waveguide features over the waveguide layer. The method also includes forming a second interconnect structure covering the first waveguide features and the waveguide layer. In addition, the first interconnect structure and the second interconnect structure are at opposite sides of the transistor.

In some embodiments, a package structure is provided. The package structure includes a first chip structure. The first chip structure includes a first electrical device and a first interconnect structure electrically connected to a front side of the first electrical device. The first chip structure further includes a first backside through via electrically connected to a backside of the first electrical device and a first waveguide layer overlapping the first electrical device. In addition, the first waveguide layer is closer to the backside of the first electrical device than the front side of the first electrical device. The first chip structure further includes first waveguide features formed over the first waveguide layer and first conductive vias formed through the first waveguide layer and electrically connected to the first backside through via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first chip structure, wherein the first chip structure comprises:
a first electrical device;
a first interconnect structure electrically connected to a front side of the first electrical device;
a first backside through via electrically connected to a backside of the first electrical device;
a first waveguide layer overlapping the first electrical device, wherein the first waveguide layer is closer to the backside of the first electrical device than the front side of the first electrical device;
first waveguide features formed over the first waveguide layer; and
first conductive vias formed through the first waveguide layer and electrically connected to the first backside through via.

2. The package structure as claimed in claim 1, further comprising:
an interposer structure, comprising:
an interposer substrate;
an optical structure formed over the interposer substrate; and
interposer-through-vias formed through the interposer substrate,
wherein the first chip structure is bonded to the interposer structure.

3. The package structure as claimed in claim 2, further comprising:
an I/O chip structure bonded to the interposer structure; and
an optical fiber attached to the interposer structure,
wherein the first chip structure is a processor chip structure.

4. The package structure as claimed in claim 2, further comprising:
a second chip structure attached to the interposer structure, wherein the second chip structure comprises:
a second electrical device;
a second interconnect structure connected to a front side of the second electrical device;
a second backside through via connected to a backside of the second electrical device;
a second waveguide layer overlapping the second electrical device;
second waveguide features formed over the second waveguide layer; and
second conductive vias formed through the second waveguide layer and electrically connected to the second backside through via,
wherein the first waveguide features, the first waveguide layer, and the second waveguide layer are made of LiNbO₃ and the second waveguide features are made of SiN.

5. The package structure as claimed in claim 1, wherein the first chip structure further comprises:
a second electrical device, wherein the first interconnect structure electrically connected to a front side of the second electrical device; and
an isolation layer formed over the first waveguide layer and vertically overlapping both the first electrical device and the second electrical device.

6. The package structure as claimed in claim 1, wherein the first chip structure further comprises:
a second electrical device, wherein the first interconnect structure electrically connected to a front side of the second electrical device; and
an amorphous Si layer formed over the first waveguide layer, wherein a width of the amorphous Si layer is greater than a width of one of the first waveguide features but is less than a width of the first waveguide layer in a cross-sectional view.

7. A package structure, comprising:
an electrical device;
a first interconnect structure electrically connected to a front side of the electrical device;
a backside through via electrically connected to a backside of the electrical device;
a waveguide layer overlapping the electrical device, wherein the waveguide layer is closer to the backside of the electrical device than the front side of the electrical device; and
first waveguide features formed over the waveguide layer.

8. The package structure as claimed in claim 7, further comprising:
conductive vias electrically connected to the backside through via,
wherein top surfaces of the conductive vias are substantially level with a top surface of the waveguide layer.

9. The package structure as claimed in claim 7, further comprising:
an amorphous Si layer covering at least one of the first waveguide features.

10. The package structure as claimed in claim 7, wherein the first waveguide features and the waveguide layer are made of a same material.

11. The package structure as claimed in claim 7, further comprising:
a second interconnect structure covering the first waveguide features and the waveguide layer,
wherein the first interconnect structure and the second interconnect structure are at opposite sides of the electrical device.

12. The package structure as claimed in claim 7, wherein the waveguide layer comprises a LiNbO₃ layer.

13. The package structure as claimed in claim 7, further comprising:
a dielectric layer formed over the first waveguide features;
metal layers embedded in the dielectric layer;
second waveguide features embedded in the dielectric layer; and
conductive bumps electrically connected to the metal layers.

14. The package structure as claimed in claim 13, wherein the metal layers are electrically connected to the backside through via.

15. A package structure, comprising:
a transistor comprising a gate structure and a source/drain structure adjacent to the gate structure;
a first interconnect structure electrically connected to a front side of the source/drain structure;
a backside through via electrically connected to a backside of the source/drain structure;
a waveguide layer formed over the backside through via;
first waveguide features formed over the waveguide layer; and
a second interconnect structure covering the first waveguide features and the waveguide layer.

16. The package structure as claimed in claim 15, wherein the first interconnect structure and the second interconnect structure are at opposite sides of the source/drain structure.

17. The package structure as claimed in claim 15, wherein the transistor further comprises:
channel layers vertically spaced apart from each other, wherein the channel layers are wrapped by the gate structure and vertically overlap with the waveguide layer.

18. The package structure as claimed in claim 15, further comprising:
second waveguide features embedded in the second interconnect structure.

19. The package structure as claimed in claim 15, further comprising:
a source/drain contact electrically connected to the front side of the source/drain structure,
wherein the first interconnect structure is electrically connected to the source/drain contact.

20. The package structure as claimed in claim 19, wherein the source/drain contact and the backside through via are at opposite sides of the source/drain structure.
